(19) United States
(12) Patent Application Publication
(10) Pub. No.: US 2026/0310744 A1
(43) Pub. Date: Oct. 8, 2026

(54) IN-MEMORY COMPUTING OF INTERACTIONS BETWEEN VARIABLES OF HIGH-ORDER FUNCTIONS

(71) Applicants: The Regents of the University of California, Oakland, CA (US); HEWLETT PACKARD ENTERPRISE DEVELOPMENT LP, Spring, TX (US)

(72) Inventors: Giacomo Pedretti, San Francisco, CA (US); Tinish Bhattacharya, Santa Barbara, CA (US); Dmitri B. Strukov, Goleta, CA (US); George H. Hutchinson, Goleta, CA (US)

(21) Appl. No.: 19/456,344

(22) Filed: Jan. 22, 2026

Related U.S. Application Data
(60) Provisional application No. 63/748,613, filed on Jan. 23, 2025.

(51) Int. Cl. G06F 17/11; G11C 13/00; G11C 16/06

(52) U.S. Cl. CPC G06F 17/11; G11C 13/0021; G11C 16/06

(57) ABSTRACT

An interaction computation circuit computes interactions between variables (e.g., gradients) of an arbitrary-order function (e.g., polynomial functions or conjunctive normal form (CNF) functions). The circuit includes one or more memory crossbar arrays (“arrays”), each configured to encode the function by associated first wires (e.g., columns) of the array with variables/literals of the function, associating second wires of the array (e.g., rows) with terms of the function, and setting memory cells of the array to an active (conducting) state if the variable/literal corresponding to the first wire coupled to the cell is included in the term corresponding to the second wire coupled to the cell. The circuit computes the interactions in parallel through in-memory computation in the array(s), including conducting a forward pass and one or more backward passes on the array(s). The inputs for the backward pass(es) are determined based on outputs of the forward pass.

### CROSS-REFERENCE TO RELATED APPLICATIONS

This application claims the benefit of US 63/748,61, the contents of which are incorporated herein by reference in their entirety.

### GOVERNMENT SUPPORT

This invention was made with government support under FA8650-23-3-7313 awarded by the Defense Advanced Research Projects Agency. The government has certain rights in the invention.

### INTRODUCTION

In many applications, such as optimization problems, machine learning (ML), physics models, control applications, operations research, etc., it is often needed or beneficial to compute certain interactions between variables of a function. An example of the aforementioned interactions is the gradient of the function at a given point, which comprises a vector of the pseudo-partial derivatives of the function at that point. Other examples of such interactions include a gain, make values, and break values, which will be discussed more below.

### BRIEF DESCRIPTION OF THE DRAWINGS

The present disclosure can be understood from the following detailed description, either alone or together with the accompanying drawings. The drawings are included to provide a further understanding of the present disclosure and are incorporated in and constitute a part of this specification. The drawings illustrate one or more examples of the present teachings and together with the description explain certain principles and operation. In the drawings:

FIGS. 1A and 1B are block diagrams schematically illustrating an example of an interaction computation circuit having a memory crossbar array. FIG. 1A shows the circuit installed in an information processing system. FIG. 1B shows the circuit as part of a peripheral hardware accelerator module.

FIGS. 2A-2D comprise block diagrams schematically illustrating an example of an interaction computation circuit for a polynomial function. FIG. 2A shows a forward pass and associated circuitry. FIG. 2B shows a backward break pass and associated circuitry. FIG. 2C shows a backward make pass and associated circuitry. FIG. 2D shows gradient calculation and associated circuitry.

FIGS. 3A-3C comprise block diagrams schematically illustrating an example of an interaction computation circuit for a CNF function. FIG. 3A shows a forward pass and associated circuitry. FIG. 3B shows a backward break pass and associated circuitry. FIG. 3C shows a backward make pass and associated circuitry.

FIG. 4 comprises a block diagram schematically illustrating an example of an interaction computation circuit with three memory crossbar arrays.

FIG. 5 comprises a block diagram schematically illustrating an example of an interaction computation circuit with two memory crossbar arrays.

FIG. 6 comprises a schematic diagram showing an example of a memory cell architecture for a memory crossbar array of an interaction computation circuit.

FIG. 7 comprises a schematic diagram showing an example of another memory cell architecture for a memory crossbar array of an interaction computation circuit.

FIG. 8 comprises a schematic diagram showing an example of another memory cell architecture for a memory crossbar array of an interaction computation circuit.

FIG. 9 comprises a schematic diagram showing an example of another memory cell architecture for a memory crossbar array of an interaction computation circuit.

FIG. 10 comprises a block diagram schematically illustrating an example of an interaction computation circuit with a backward memory crossbar array having the memory cell architecture of FIG. 9.

### DETAILED DESCRIPTION

Computing variable interactions may be an important part of various applications. For instance, such interactions (e.g., gradients) may be used for things such as training the weights in modern Deep Neural Networks (DNN), or in physics-inspired computing paradigms including Ising machines (IMs) or closely related approaches with Hopfield neural networks (HNNs) and Boltzmann machines (BMs). For instance, a HNN consists of a recurrently connected network of pairwise symmetrically coupled graded-response neurons, and during operation of the HNN the neuron states are continuously updated to seek the minimum of an associated scalar energy function (e.g., a Hamiltonian function in the context of Ising models), with each such update depending on a computation of the gradient at a given point to seek out the minimum of the function based on gradient descent or similar methods. As another example, algorithms for solving various well known problems, such as polynomial unconstrained binary optimization (PUBO) problems, K-Boolean-satisfiability (K-SAT) problems, or various other problems, often rely on the iterative computation of interactions between variables (e.g., gradient, gain, etc.) of an objective function.

But computation of such interactions between variables can sometimes be computationally expensive for general purpose processors, and thus may require very powerful (and hence energy-hungry) computers to solve in reasonable timeframes. To provide such computations more efficiently (in terms of time, energy/power consumed, etc.), a hardware accelerator that specializes in such computations may be needed. Among other things, such hardware accelerators could greatly improve the performance of various state-of-the-art optimization algorithms that utilize gradient descent, conjugate gradient, or similar methods, which may be at the core of various control, machine learning, and operations research applications.

Some hardware accelerator architectures have been proposed that can compute gradients of second-order polynomial functions (quadratic polynomials). Order is used herein to refer generally to the complexity of the function, and is denoted by K. In the case of polynomials, order refers to the degree of the polynomial. In the case of Boolean functions in Conjunctive Normal Form (CNF), the order refers to the maximum number of literals (variables or their complements) per clause. For instance, IMs/HNNs have been extensively applied to solving quadratic unconstrained binary optimization (QUBO) problems where the minimum of an arbitrary quadratic (K=2) binary function is sought.

However, computation of the interactions (e.g., gradients) for functions with order higher than two is more complicated, and an efficient hardware accelerator architecture for computing the variable interactions of such higher-order functions is lacking. Existing architectures for second order functions generally cannot be extended to higher order functions in a manner that is efficient in terms of size, complexity, and cost. Extending those architectures to higher order problems may entail an increase in the complexity and size of the circuitry that scales rapidly (e.g., exponentially) with the order K of the problem, which may make it infeasible for large K.

For instance, a second-order HNN has been proposed which utilizes a memory crossbar array for massively parallel in-memory computation of gradients of a second order Hamiltonian function. However, a straightforward extension of this architecture to handle functions of a higher order (K≥3) may require the crossbar array to have about N^{K} cells, where N is the number of neurons and K is the order of the function. Thus, with larger values of N and K, the crossbar array may quickly become infeasibly large, making this approach impractical for many problems.

Thus, efficient architectures for hardware accelerators to compute variable interactions of higher order functions are lacking. Meanwhile, functions of higher K can represent increasingly important and challenging problems. For example, polynomial unconstrained binary optimization (PUBO) problems are described by K-degree polynomials (with K≥3) and naturally arise in protein folding and other first-principle calculation methods and operations research. Notably, K grows linearly with the size of molecular system (molecular orbitals) in PUBO approaches for calculating electronic structure, making the space-inefficient hardware accelerator architecture described above infeasible for such problems. Another example is the K-Boolean-satisfiability (K-SAT) problem, which can go from polynomial to exponential runtime as K increases from 2 to 3, and even worse when K exceeds 3. While higher order (K>3) functions can often be converted to a lower order (e.g., K=3) representation through an order reduction process, this requires a polynomial increase in the variables, potentially increasing the runtime with increasing K.

To address these and other issues, the present application provides examples of an in-memory computation circuit comprising one or more memory crossbar arrays (“arrays”) that can efficiently compute, in parallel, interactions between variables of an arbitrarily high-order function in its native space (i.e., without requiring order reduction techniques or conversion between forms). This in-memory computation circuit may form the basis of a hardware accelerator, such as a high-order gradient computation accelerator, high-order gain computation accelerator, high-order HNN, etc.

In some examples, the variables whose interactions are computed are variables of an objective function of an optimization problem, particularly, in some examples, a combinatorial optimization problem. In some examples, the objective function is a polynomial with a degree of K≥3, such as the objective function of a polynomial unconstrained binary optimization (PUBO) problem. In some examples, the objective function is a Boolean equation in conjunctive normal form (CNF) with complexity K≥3, such as the objective function of a K-complexity CNF satisfiability problem (K-CNFSAT or K-SAT) with K≥3.

In some examples, the computed interactions between the variables are gradients (or similar values). Computing gradients is useful across many applications, such as in deep neural networks, Ising machines, Hopfield Neural Networks, Boltzmann machines, and others. In other examples, computed interactions between the variables include identifications of make and/or break values, which may be used in various algorithms for solving K-SAT problems.

The computations of such interactions (e.g., gradients, make values, break values, etc.) can be very challenging for problems with order greater than two (greater than quadratic). In particular, with some architectures for computing such interactions, the complexity and size of the circuitry (and hence costs) may scale exponentially with the order of the problem, which may make it infeasible to apply such approaches to higher-order problems. However, the size of certain in-memory computation circuits disclosed herein may scale linearly with the number of variables and terms in the function, independently of its order. Thus, some examples disclosed herein can form the basis of solvers that can compute the interactions for high-order problems while also being space efficient (and hence cost efficient).

In some examples, one or more memory crossbar arrays encode the objective function by storing values in the memory cells thereof. Specifically, one set of wires (e.g., the rows) is assigned to the terms (e.g., monomials or clauses) of the function (“term-wires”), while the other set of wires (e.g., the columns) is assigned to the variables and/or complements thereof (“variable-wires”). At each intersection of a term-wire and a variable-wire there is a memory cell which can be set to different resistance/conductance states. For instance, each memory cell may include a memristor, floating gate transistor (flash memory cell), or other memory element capable of changing resistance/conductance between an active (conductive) state and an inactive (substantially non-conductive) state. To encode the function in the array, each memory cell may be set to an active (conductive) state if the variable represented by the corresponding variable-wire is found in the term represented by the corresponding term-wire.

Interactions between variables may be computed by performing a forward pass and one or more backward pass(es) on these memory crossbar array(s). In some examples, a single array is used for both forward and backward passes. In other examples, multiple arrays may be used, with a forward pass being performed on one array and one or more backward passes being performed on one or more other arrays. A forward pass comprises applying to the variable-wires of an array respective input voltages corresponding to value assignments for the variables (or complements thereof, in some examples). A backward pass comprises calculating backward-pass input voltages for each term of the function based on the outputs of the term-wires from the forward pass and applying the backward-pass inputs to the term-wires of an array. In some cases, the outputs of the variable-wires from the backward pass(es) are themselves the computed interactions of interest, while in other cases they may be intermediate values which are used to determine the interactions of interest through subsequent processing.

Turning now to the figures, various devices, systems, and methods in accordance with aspects of the present disclosure will be described.

### I. Interaction Computation Circuit, General Architecture

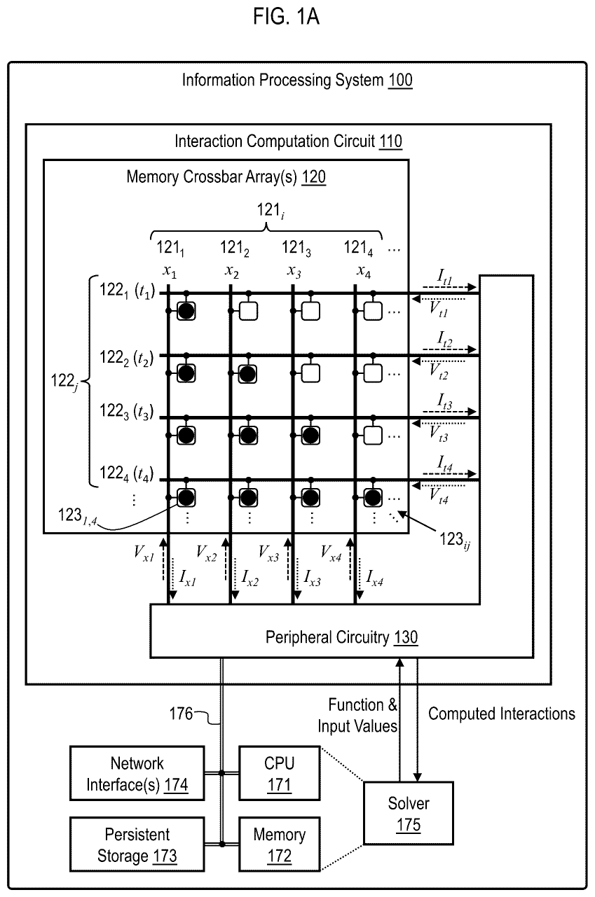

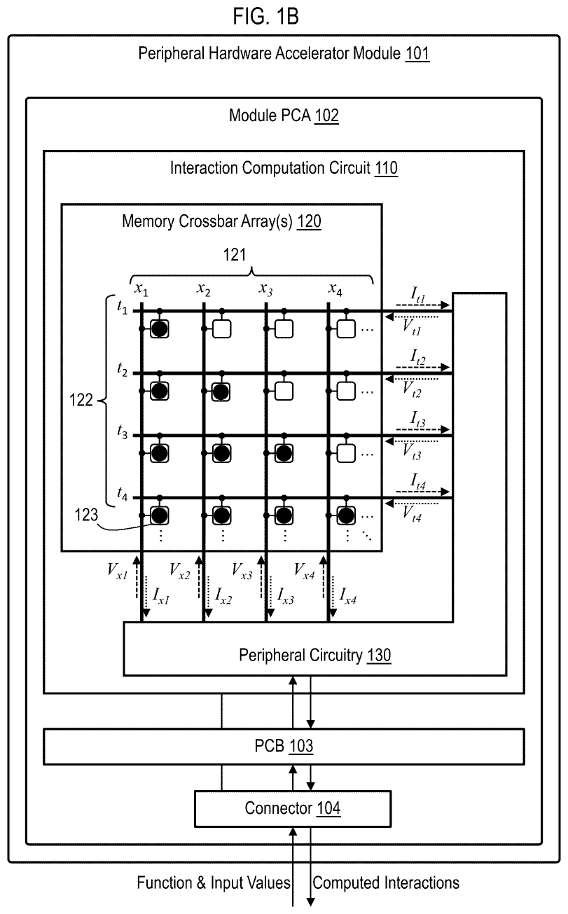

FIGS. 1A and 1B are schematic block diagrams conceptually illustrating an example of an interaction computation circuit 110 (“circuit 110”). FIGS. 1A and 1B are schematic in nature and not intended to illustrate shapes, sizes, positional relationships, or other structural details accurately or to scale. Components which are not illustrated in FIGS. 1A and 1B may also be included in some examples disclosed herein, or one or more components illustrated in FIGS. 1A and 1B may be omitted from some examples disclosed herein.

The circuit 110 may be used as part of a larger information processing system (e.g., server, personal computer, etc.). In some cases, the circuit 110 is tightly integrated into the system, such as by being directly mounted and/or soldered to a same system board as a CPU of the system. In other cases, the circuit 110 may be part of a peripheral module that is removably connected to the system board via a cable or connector. For instance, FIG. 1A shows the circuit 110 in the context of an information processing system 100 and FIG. 1B shows the circuit 110 in the context of a peripheral hardware accelerator module. These two contexts will be described in more detail below, following description of the circuit 110 itself.

The interaction computation circuit 110 may be a hardware accelerator that is specialized in computation of interactions between variables of high-order functions. In some examples, these functions may include polynomial functions, CNF functions, or others. In some examples, the interactions comprise gradients, gain, break values, make values, or other interactions between variables. The interaction computation circuit 110 may thus form, or be used in conjunction with, a solver that utilizes the computed interactions as part of solving a problem.

For instance, in some examples, the circuit 110 may process high order polynomial functions with binary input variables (taking only values 0 or 1). Such functions may serve as the objective function of a polynomial unconstrained binary optimization (PUBO) problem, in some examples. In such examples, the interactions that are calculated may comprise gradients. These gradients may be used, for example, as part of a gradient descent, conjugate gradient, or other similar methods to find a minimum (or other optimization criterion) of the objective function. Thus, in such examples, the interaction computation circuit 110 may form a part of a PUBO solver.

In other examples, the function is a high order CNF function, and the interactions that are calculated may comprise a gain and/or break values. This may allow the circuit to form a part of a solver for Constraint Satisfaction Problems (CSPs), like SAT and MAXSAT, in native space without potentially time-consuming conversion to an equivalent PUBO form. A CNF Boolean function comprises a conjunction (AND) of clauses, where a clause is a disjunction (OR) of literals, i.e., normal or complementary variables. The goal in the K-SAT problem, known as NP-hard for K≥3, is to find a variable assignment that satisfies all clauses of the given CNF function, with up to K literals per clause. The circuit 110 may allow for parallel computation of Boolean per-variable gain values. (A gain value is commonly used in SAT community to describe the change in the number of satisfied clauses after flipping a variable. It is effectively the negative of the pseudo partial derivative with respect to that variable of an equivalent PUBO energy function.) When all of these variable gain values are taken together, they may be analogous to the gradient.

In other examples, the function may be some other form of function, such as a polynomial with scalar variables or some other function.

Some examples of the circuit 110 may be specialized in computing interactions for just one type of function. Other examples of the circuit 110 may be capable of processing multiple different types of functions.

Circuit 110 comprises one or more memory crossbar arrays 120 (“arrays 120”) and peripheral circuitry 130 to support the arrays 120. Each array 120 includes a set of first wires 121 and a set of second wires 122 which extend transverse to the first wires 121, forming a crossbar. Arrayed in this crossbar are memory cells 123 (“cells 123”) (only one is labeled in FIGS. 1A and 1B, but multiple are shown). Each memory cell 123 is disposed at a crossing of a corresponding first wire 121 and a corresponding second wire 122 and is electrically connected to both (note that the first wires 121 and second wires 122 cross each other but do not directly electrically connect to each other at the crossing).

The first wires 121 in a portion of the array 120 may be identified herein by an index i, and thus may also be referred to herein as first wires 121ᵢ, with wire 121₁ being a first one of the first wires 121 in the portion, wire 121₂ being a second one of the first wires 121 in the portion, and so on. The second wires 122 in the same portion of the array 120 may be identified by an index j, and thus may also be referred to herein as second wires 122j, with wire 122₁ being a first one of the second wires 121 in the portion, wire 122₂ being a second one of the second wires 120 in the portion, and so on. FIG. 1A shows first wires 121₁ through 121₄ and second wires 122₁ to 122₄ as examples, but any number N of first wires 121 and any number M of second wires may be included in the portion of the array 120. Cells 123 may be identified herein by a combination of the indices i and j, and thus may also be referred to herein as cells 123ᵢⱼ, with the indices i and j indicating which if the first wires 121, and second wires 122j the cell 123ᵢⱼ is connected to. Specifically, each memory cell 123ᵢⱼ includes at least two terminals, with one terminal being connected to a corresponding first wire 121, and another terminal connected to a corresponding second wire 122ⱼ. For instance, memory cell 123_{1,4}, shown in FIG. 1A, has a first terminal connected to first wire 121₁ (i=1) and a second terminal connected to second wire 122₄ (j=4).

In some examples, each memory cell 123 can store binary values by switching between an essentially non-conducting or “Inactive” state (a state with very high resistance) and a conducting or “Active” state (a state with lower resistance). In the description below, it is assumed that the Active (conducting) state is associated with a logical 1, while the Inactive (non-conducting) state may be associated with a logical 0, although these conventions could be reversed in some examples. In some examples, if the memory cell 123 is in the active state and a predetermined read voltage V₀ is applied across the memory cell 123, then a predetermined current I₀ will be output therefrom, whereas if the memory cell 123 in a reset state and the predetermined read voltage V₀ is applied across the memory cell 123 then essentially zero current will be output therefrom. The direction the current flows may depend on the polarity of the voltage applied. For instance, if the read voltage V₀ is applied to a first wire 121, while a ground/reference voltage (0V) is applied to a second wire 122, and the memory cell 123ᵢⱼ is Active (conducting), then a current I₀ will flow from the first wire 121, to the second wire 122ⱼ. On the other hand, if the read voltage V₀ is applied to a second wire 122ⱼ while the ground voltage (0V) is applied to a first wire 121ᵢ and the memory cell 123ᵢⱼ is Active (conducting), then a current I₀ will flow in the opposite direction from the second wire 122ⱼ to the first wire 121ᵢ.

In some examples, memory cells 123 comprise memristors, which will be described in greater detail below. In other examples, memory cells 123 comprise flash (floating gate) memory cells. In other examples, any other memory technology may be used which can be programmed into the conducting and non-conducting states described above.

The circuit 110 is configured to program or encode a function of arbitrary order into the arrays 120 by setting or resetting appropriate memory cells 123. The variables of the function and/or the complements thereof are respectively assigned to corresponding first wires 121. Thus, the first wires 121 may also be referred to herein as variable-wires 121. Equivalently, this assignment of variables/complements may also be described as assigning “literals” to the first wires 121, wherein literal refers to a variable or its complement in the context of CNF functions. Variables are denoted herein with the character x and a numerical index, such as x₁, x₂, x₃, x₄, . . . and literals are denoted herein by the character l and a numerical index, such as l₁, l₂, l₃, l₄, . . . but this is merely a convention used herein for ease of description. A complement of a variable is the logical/binary opposite and is indicated herein by placing a bar above the variable's symbol. For instance, if x₁ is a variable then x̅₁̅ is its complement, and x̅₁̅=1 implies x₁=0 while x₁=0 implies x̅₁̅=1.

Furthermore, the terms of the function (excluding terms having only a constant) are respectively assigned to corresponding second wires 122. Thus, the second wires 122 may also be referred to herein as term-wires 122. The terms are denoted herein by a character t and a numerical index, such as t₁, t₂, t₃, t₄, . . . . In the case of a polynomial function, terms of the function constitute monomials. Each of these monomials includes a product of one or more variables and/or one or more constants, with monomials being separated from one another in the expression of the function by addition or subtraction. For instance, in the polynomial H=a₁x₁+a₂x₁x₂+a₃x₁x₂x₃+a₄x₁x₂x₃x₄ the terms of the function include: the monomial t=a₁x₁, the monomial t₂=a₂x₁x₂, the monomial t₃=a₃x₁x₂x₃, and the monomial t=a₄x₁x₂x₃x₄, wherein a₁, a₂, a₃, a₄, . . . are constants and x₁, x₂, x₃, x₄ are variables. In the case of a CNF function, terms of the function constitute clauses, wherein each clause comprises up to K literals in disjunction (Boolean OR) and each of the clauses are joined in conjunction (Boolean AND), with K being the order of the function. For instance, in the K=4 CNF function CNF=(x̅₁̅∨x₂∨x₃∨x₄) ∧(x̅₇̅ ∨x₂), the terms include: a first clause t₁=x̅₁̅ ∨x̅₂̅∨x̅₃̅ ∨x₄ and a second clause t₂=x̅₁̅∨x₂, wherein x₁, x₂, x₃, x₄ are variables, “V” is the disjunction (Boolean OR) operator, and “A” is the conjunction (Boolean AND) operator.

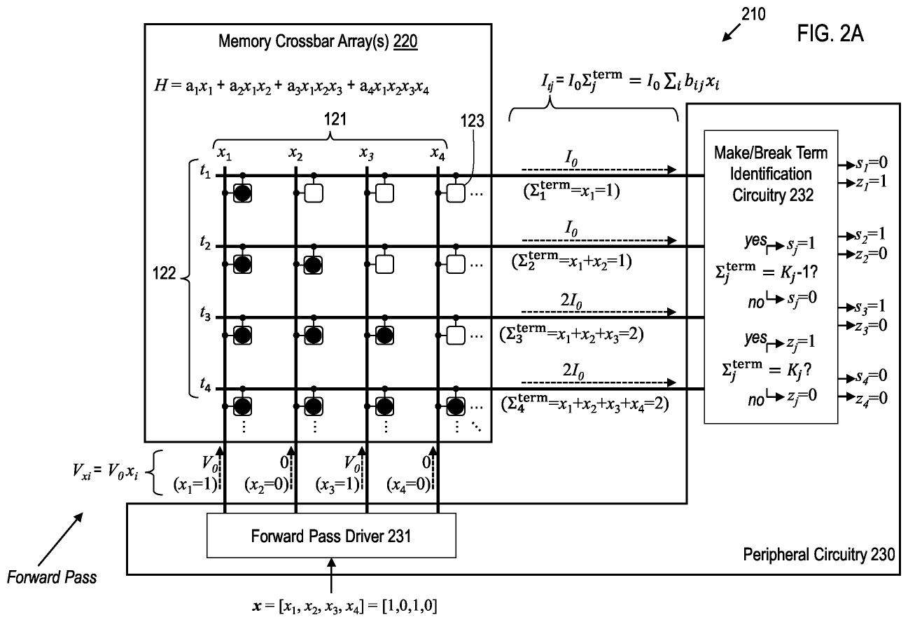

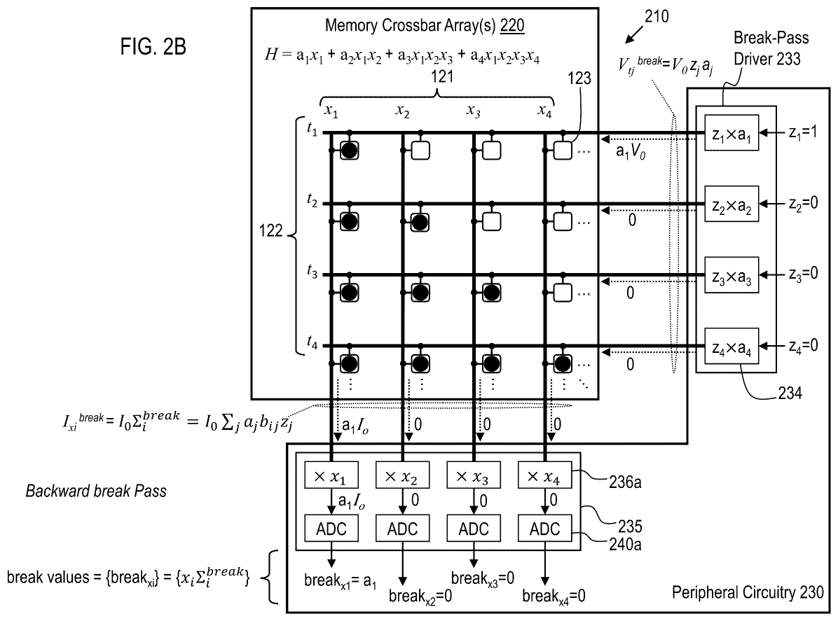

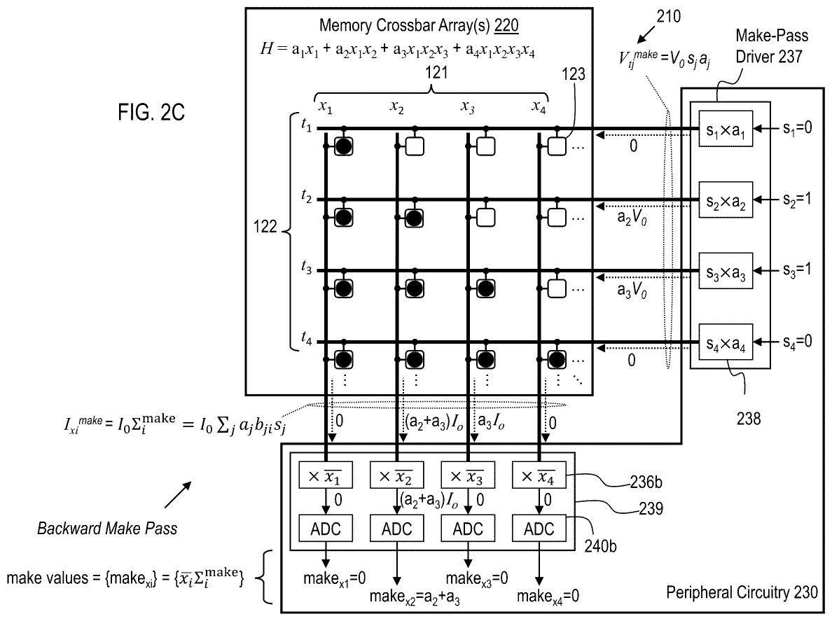

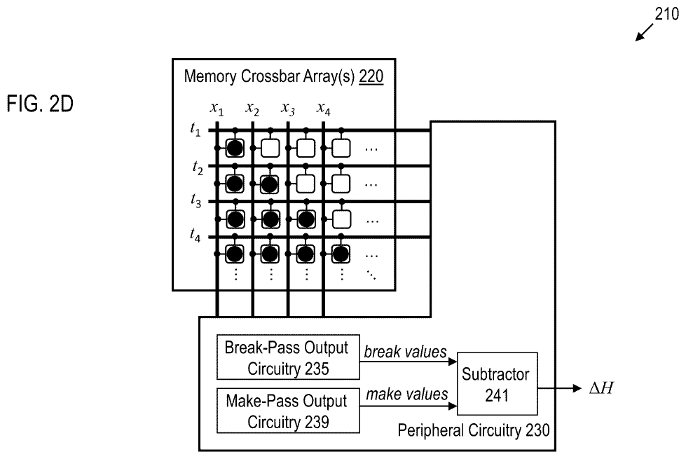

Herein, it is assumed for ease of description that the variables/literals are assigned to first wires 121 such that their respective indices correspond. Specifically, in the case of a polynomial function, the variables are referred to herein using the same index i that is used for the variable lines 121ᵢ, and each variable x, is assigned to a corresponding variable wire 121, (e.g., variable x₁ is assigned to wire 121₁, variable x₂ is assigned to wire 121₂, and so on). In the case of a CNF function, literals are referred to herein using the index i while variables are referred to using the index k, each literal lᵢ is assigned to a corresponding variable wire 121, (e.g., literal l₁ is assigned to wire 121₁, literal l₂ is assigned to wire 121₂, and so on), which results in each variable xₖ being assigned to a corresponding variable wire 121ᵢ₌₂ₖ₋₁ (e.g., variable x₁ is assigned to wire 121₁, variable x₂ is assigned to wire 121₃, and so on). FIGS. 1 and 2 show variables xᵢ being assigned to variable lines 121, as for encoding of a polynomial function, but this is merely one example and literals l, could instead be assigned to the variable lines 121, if a CNF function is to be encoded.

Similarly, it is assumed that the terms are assigned to second wires 122 such that their respective indices correspond, i.e., term tⱼ is assigned to wire 122j (e.g., term t₁ is assigned to wire 122₁, term t₂ is assigned to wire 122₂, and so on).

However, the variables/literals may be assigned to the first wires 121 and the terms to the second wires 122 in any arbitrary fashion, although it should be noted that the formulas and descriptions herein would need to be translated accordingly to reflect the altered assignments.

The function may be encoded in the array 120 by setting the memory cells 123 to the Active state if the variable/literal associated with the variable wire 121 coupled to the memory cell 123 is included in the term associated with the term wire 122 coupled to the memory cell 123, and resetting them to Inactive otherwise. In other words, for each combination of i and j, memory cell 123E is set to Active if the variable xᵢ (in the case of polynomial function) or literal lᵢ (in the case of CNF function) is included in the term tⱼ and is reset to Inactive otherwise. The state of the memory cell 123_{E} may be denoted herein as bᵢⱼ, wherein bᵢⱼ=1 if the memory cell 123, is set to the Active state and bᵢⱼ=0 if the memory cell 123ᵢⱼ is set to the Inactive state.

For instance, FIGS. 1A and 1B show one hypothetical encoding of the function H=a₁x₁+a₂x₁x₂+a₃x₁x₂x₃+a₄x₁x₂x₃x₄, wherein memory cells 123 that are set to Active are illustrated with a dark circle therein while memory cells 123 that are reset to Inactive are illustrated as empty. Considering the variable x₁, it is included in each of the monomials t₁=a₁x₁, t₂=a₂x₁x₂, t₃=a₃x₁x₂x₃, and t₄=a₄x₁x₂x₃x₄, and therefore in the 1st column (i=1) the memory cells 123_{1,1}, 123_{1,2}, 123_{1,3}, and 123_{1,4} are set to the Active state. Considering the variable x₂, it is included in the monomials t₂=a₂x₁x₂, t₃=a₃x₁x₂x₃, and t₄=a₄x₁x₂x₃x₄, but is not included in the monomial t₁=a₁x₁, and therefore in the 2^{nd} column (i=2) the memory cells 123_{2,2}, 123_{2,3}, and 123_{2,4} are set to the Active state while memory cell 123_{2,1} is set to Inactive. Considering the variable x₃, it is included in the monomials t₃=a₃x₁x₂x₃ and t₄=a₄x₁x₂x₃x₄, but is not included in the monomials t₁=a₁x₁ or t₂=a₂x₁x₂, and therefore in the 3^{rd} column (i=3) the memory cells 123_{3,3} and 123_{3,4} are set to the Active state while memory cells 123_{3,1} and 123_{3,2} are set to Inactive. Considering the variable x₄, it is included in the monomial t₄=a₄x₁x₂x₃x₄, but is not included in the monomials t₁=a₁x₁, t₂=a₂x₁x₂, or t₃=a₃x₁x₂x₃, and therefore in the 4^{rd} column (i=4) the memory cell 123_{3,4} is set to the Active state while memory cells 123_{4,1}, and 123_{4,2}, 123_{4,3} and are set to Inactive. Although the encoding shown in FIG. 1 is for a specific polynomial, it should be understood that this is just one example and any arbitrary polynomial or CNF function could be encoded instead in a like fashion.

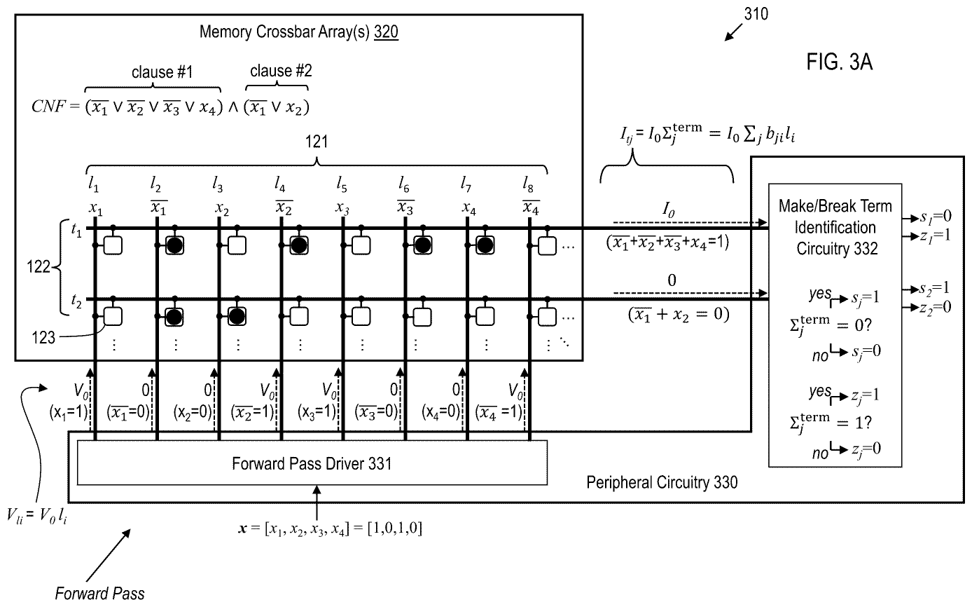

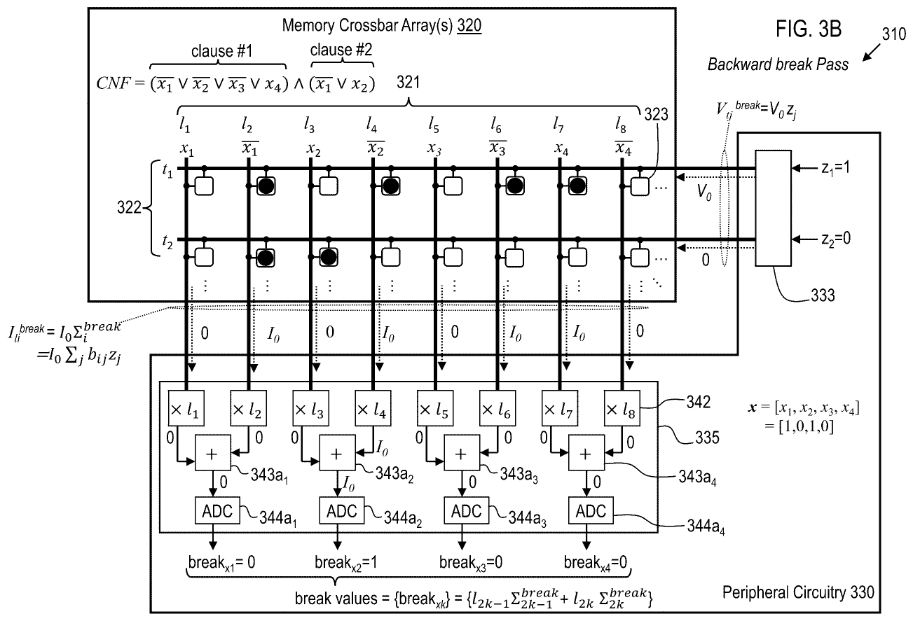

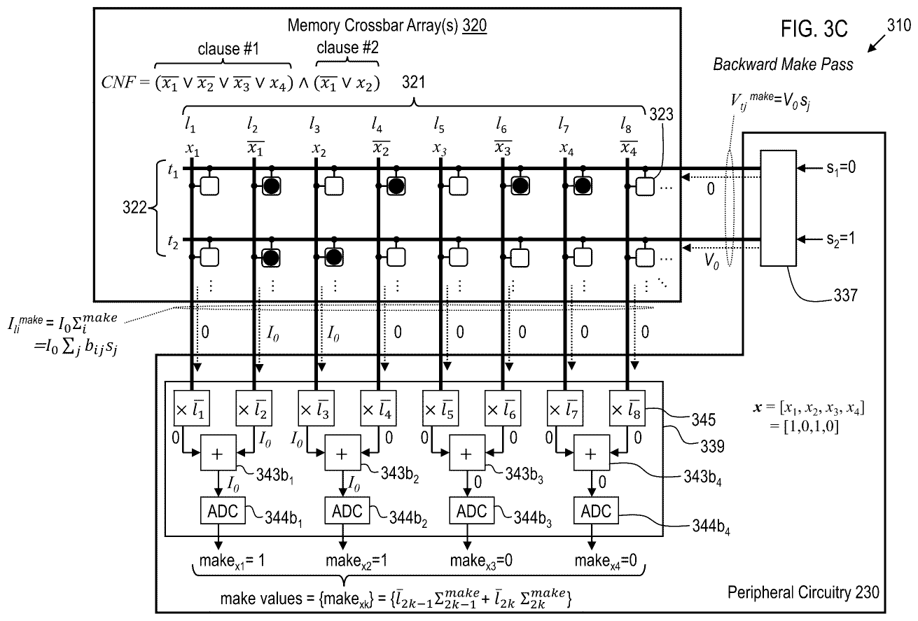

Notice that the order (e.g., degree) of the function does not directly affect whether it can be encoded in the array 120. Put another way, the minimum size of the array 120 that can fit the function is not dictated (directly) by the order of the function. Instead, the minimum size of the array 120 that can fit a given function is dictated by the number of variables of the function and the number of terms thereof. The number of variables determines the minimum number of columns of memory cells 123 that are needed (a column corresponding to a direction that the variable wires 121 extend), while the number of terms determines the minimum number of rows of memory cells 123. Put another way, if the array 120 has N rows and M columns of memory cells 123, then it can encode any polynomial or CNF function of arbitrary order as long as the number of variables thereof is equal to or less than M (for a polynomial) or M/2 (for a CNF) and the number of terms thereof is equal to or less than N. (The reason the largest CNF function that will fit has only half as many variables as the largest polynomial function that will fit is that encoding the CNF function may entail assigning both the variables and their complements to variable wires 121, as shown in FIG. 3A, whereas encoding the polynomial function may entail assigning just the variables to the variable wires 121, as shown in FIG. 2A.)

If the array 120 has more cells 123 than are needed to encode the given function, then the function can be encoded in a portion of the array 120 and memory cells 123 that are outside of this portion may be placed in an inactive state. More specifically, a subset of wires 121 are assigned to variables and/or complements of the function and a subset of wires 122 are assigned to terms, and any memory cell that is not connected to wires 121 and 122 of both subsets are “excess” cells 123 that are not being used to encode the function, and these excess cells 123 can be set to the inactive state.

In some examples, the function that is encoded into the array(s) 120 can be selectively programmed into the arrays 120 by an external source, such as a CPU 171 in system 100 (described below). For instance, the external source may send the peripheral circuitry 130 an identification of the parameters of the function that is to be encoded and then the peripheral circuitry 130 may encode the function in the array(s) 120 by driving the memory cells 123 to set their states. Peripheral circuitry 130 may include various array drivers which are configured to control the setting/resting and reading of the memory cells 123. Such drivers for driving memory arrays are familiar to those of ordinary skill in the art and thus are not shown in detail herein. In these examples, any arbitrary function can be encoded in the arrays 120.

With the function encoded in one or more arrays 120 as described above, interactions between the variables of the function may be computed by assigning a value to each of the variables and performing forward and backward passes on the array(s) 120 based on those values. In some examples, a single memory crossbar array 120 is used for both forward and backward passes. In other examples, multiple arrays 120 may be used (each encoding the function as described above), with a forward pass being performed on one array 120 and one or more backward passes being performed on one or more other arrays 120. The peripheral circuitry 130 may control the application of the inputs to the arrays 120 during the forward and backward passes, as well as receiving and processing the outputs of the arrays 120, as will be described in greater detail below.

In some examples, a cycle of forward and backward passes may be repeated iteratively as part of a solver algorithm. For instance, some solver algorithms may iteratively calculate the interactions between variables (e.g., gradients) at various points, with each successive point being chosen based on the previous calculation of interactions, with the iterations repeating until some convergence criterion is met. For instance, a gradient descent method may be utilized, in some cases. In some examples, new values are inputted to the circuit 110 for each iteration and newly calculated interactions based thereon may be output. Other circuitry may process the calculated interactions to determine the new inputs for the next iteration, according to whatever solver algorithm is being implemented.

In some cases, this other circuitry may be external to the circuit 110. For instance, solver logic 175 (described below) may control aspects of the algorithm execution other than computation of the interactions, and this solver logic 175 may input new values of the variables into the circuit 110 and receive the computed interactions from the circuitry 110 with each iteration.

In other examples, the circuitry that receives the calculated interactions and generates new inputs may itself be part of the circuit 110. For instance, if the circuit 110 is part of a higher order HNN then the peripheral circuitry 130 may include neurons (not illustrated), e.g., differential-output operational amplifiers, which may be arranged to receive the computed interactions and then feed the outputs from the neurons back into the array(s) 120 as the inputs for a next iteration of calculations.

As mentioned, each iteration comprises a forward pass and one or more backward passes. A forward pass comprises applying to the variable-wires 121, input voltages Vₓᵢ (in the case of a polynomial) or Vₗᵢ (in the case of a CNF), wherein the voltages Vₓᵢ or Vₗᵢ correspond to the value assignments for the variables xᵢ or literals lᵢ. The read voltage V₀ may be applied to wire 121, if the value of the corresponding xᵢ or lᵢ equals 1 while the ground voltage (0V) may be applied to wire 121, if the value of the corresponding xᵢ or l, equals 0. In other words, for each value of i, Vₓᵢ=V₀·xᵢ or Vₗᵢ=V₀·lᵢ Concurrently with the application of these voltages Vₓᵢ or Vₗᵢ to the variable-wires 121ᵢ, the ground voltage (0V) is applied to each of the term-wires 122. As a result of the application of these voltages to variable-wires 121 and term wires 122, output currents IJ are received at the term wires 122j. For each wire 122j, the magnitude of the current Iₜj will be equal to

$${I}_{0} {\sum }_{j}^{term} ,$$

which is equal to I₀Σᵢ bⱼᵢxᵢ if the function is a polynomial function or to I₀ Σⱼ bⱼᵢlᵢ if the function is a CNF function.

The values Z bⱼᵢxᵢ or Σⱼ bⱼᵢlᵢ which are encoded in the output currents Iₜⱼ from the forward pass may be described as term variable sums, wherein each term variable sum is the sum of the variables that are included in the term tⱼ. Thus, the forward pass may be described as computing term variable sums. The term variable sums calculated in the forward pass may be used to identify which terms tⱼ are make terms or break terms in subsequent backward passes.

In addition, in some examples where the function is a CNF function, the term variable sums may be used by peripheral circuitry 130 to determine whether each clause of the CNF is satisfied. This information can be used to determine if an optimization criterion of the problem is met (e.g., if all clauses are satisfied). If the optimization criterion is not net met, then the backward pass(es) may be performed. In some cases, if the criterion is met, then the process may end after the forward pass without proceeding to the backward pass(es).

The term variable sums calculated in the forward pass may be used to determine the input voltages to apply to the array 120 in the backward pass(es). Specifically, in a backward pass the peripheral circuitry 130 may calculate backward-pass input voltages Vₜⱼ based on the output currents Iₜⱼ from the forward pass and applies Vₜ to the term-wires 122. Examples of how the voltage Vₜⱼ are determined by the peripheral circuitry 130 are explained below. Concurrently with the application of the voltages Vₜⱼ to the term wires 122, the ground voltage (0V) is applied to each of the variable-wires 121, and consequently output currents Iₓᵢ or Iₗᵢ are received on variable wires 121i. For the outputs Iₓᵢ or Iₗᵢ, the magnitude of the current will depend on the applied voltages Vₜⱼ and on the states of the memory cells 123 (i.e., bᵢⱼ), as will be described below.

The outputs Iₓᵢ or Iₗᵢ from the one or more backward passes may then be processed to compute the interactions of interest, such as make values, break values, gradients, gain, etc. In some examples, the one or more backward passes may include a backward make pass, which is used to compute make values for each variable xᵢ. Furthermore, in some examples, the one or more backward passes may include a backward break pass, which is used to compute break values for each variable xᵢ. In some examples, the make and/or break values are the interactions of interest, and they may be sent to other components for further processing. In some examples, a gradient or a gain may be the interaction of interest, and in such cases this gradient or gain may be determined based on the make/break values (e.g., by subtracting the break values from make values, or vice versa). This gradient or gain can then be used to determine a next input for the forward pass, and the process may be repeated over and over again until an optimization criterion is met. This may, for example, form the basis of a high-order HNN, PUBO solver, SAT solver, or other solver that iteratively calculated gradients or gains. In some examples, only the break values need be determined, as certain optimization algorithms, such as WalkSAT/SKC, need only the break values to determine a next input for the forward pass. Examples of the aforementioned backward passes and the calculation of make values, break values, and/or gradient/gain based thereon will be described in greater detail below in relation to FIG. 2A et seq.

As shown in FIG. 1A, the interaction computation circuit 110 can be part of an information processing system 100 (“system 100”). The system 100 may include a computer, such as a server, a personal computer, a high-performance computing (HPC) system, etc. In addition to the interaction computation circuit 110, the system 100 may also comprise a central processing unit (CPU) 171, a memory 172, persistent data storage 173, a network interface 174, and one or more communications paths (e.g., busses). System 100 may include other components (not illustrated), such as a system board to which CPU 171 is mounted, various peripheral devices, power supply units, and so on as would be familiar to one of ordinary skill in the art.

The term “CPU” is used herein to refer to a primary processor that controls the operation of the system 100 as a whole, such as by running an operating system (OS) of the system 100, but this is not limited to processors that are marketed as or commonly considered as CPUs. The CPU 171 may include any type of processor, including a microprocessor, an Application-Specific Integrated Circuit (ASIC), or other processor. In some examples, the CPU 171 is, or is part of, a System-on-Chip (SoC), which refers to a combination of a processor and various other components disposed together on the same package or chip. Some examples of the system 100 may have a single CPU 171, while in other examples system 100 may have multiple CPUs 171.

The memory 172 is communicably connected to CPU 171 via the one or more communication paths 176. The memory 172 includes any non-transitory data storage media that the CPU 171 can access, and stores instructions executable by the CPU 171, which may include operating system instructions, instructions for various applications, or other instructions. Memory 172 may include random-access memory (RAM), volatile memory, non-volatile (persistent) memory, or any other type of data storage device suitable for access by the CPUs 171.

In some examples, CPU 171 and memory 172 may together form solver logic 175 configured to execute an algorithm that solves a particular type of problem, such as a PUBO problem, SAT solver, etc. The solver logic 175 may be formed by the CPU 171 executing machine-readable instructions stored in memory 172. In some examples, the solver algorithm executed by the solver logic 175 may include any existing algorithm for solving a problem which relies upon the calculation of interactions between variables, such as gradients, gain, break values, and/or make values. Examples of such problems include optimization problems (which may include a PUBO problem), CSPs (e.g., SAT, MAXSAT, etc.), and the like. These algorithms generally involve solving (e.g., minimizing) a particular objective function by iteratively calculating the interactions between variables at various points, with the calculated interactions of each iteration informing the inputs used in the next iteration, as described above. For each iteration of the algorithm, the solver logic 175 may determine and input to the circuitry 110 the values to be used in the current iteration, the circuitry 110 may then calculate the interactions and output the result to the solver 175, and then the solver logic 175 may use the calculated interactions to determine the input values to use for the next iteration. The solver logic 175 may also perform other aspects of the solver algorithm such as determining when an optimization/convergence criterion is met. Thus, the solver logic 175 together with the circuit 110 form a complete solver. Put another way, the circuit 110 may form the part of the solver which calculates the interactions and the solver logic 175 may form remaining parts of the solver which carry out other functions.

In other examples, solver logic 175 is omitted. For instance, in some examples, circuitry 110 may include all of the logic for performing the solver algorithm, and not just the logic for calculating the interactions. In such examples, the CPU 171 may provide some inputs to circuitry 110, such as to define the bounds of the problem to be solved, but then the circuitry 110 may thereafter perform all of the solver algorithm itself.

One of ordinary skill in the art would understand how to implement the logic for performing parts of the solver algorithm other than the calculation of the interactions, and thus this logic is not shown in greater detail herein.

Persistent storage 173 may include data storage devices that are non-volatile, meaning they continue to store data even after power is removed. For instance, persistent storage 173 may include hard-disk drives (HDD), solid-state drives (SSD), or other data storage drives. Persistent storage 173 is connected to memory 172 and CPU 171 via one or more communication paths 176. In some examples where memory 172 is persistent, separate persistent storage 173 may be omitted, or, putting the same point a different way, memory 172 and persistent storage 173 may be merged (e.g., provided by the same device(s)).

Network interface(s) 174 comprise one or more interfaces for communicably connecting with other devices, either directly or via network. These network interface(s) 174 may include one or more ports (e.g., receptacles configured to receive connectors of a cable), such as Ethernet ports or ports according to any other desired communication protocol. The network interface(s) 174 may also include wireless communication interfaces, such as Wi-Fi, Bluetooth, cellular, or other wireless communication interfaces, which may include an antenna, transceiver, etc. The network interface(s) 174 may also include circuitry to drive the aforementioned components and to perform protocol-specific functions, such as translation between physical layer and higher layers (e.g., data link layer, network layer, etc.), such as an Ethernet PHY chip, Wi-Fi PHY chip, or others. Network interface(s) 174 may be connected to other components of the system 100 via one or more communication paths 176.

The communication paths 176 include electrical circuitry to communicably connect components of the system 100. These may include electrical traces in/on a system board, wires of cables, or any other electrical circuitry suitable for communication of data between components. In some examples, the communication paths 176 may comprise one or more communication buses, such as a system bus, an input/output bus, a peripheral component interconnect express (PCIe) bus, an inter-integrated circuitry (I2C) bus, and/or any of the other various buses used in computing devices. Although FIG. 1 shows the communication paths 176 all connected together as if they are one bus which is connected to each component, this is merely for ease of illustration and in practice multiple different buses may be present and they are not necessarily each connected to every component or to each other.

FIG. 1A shows the hardware accelerator comprising the circuit 110 in an installed state in the system 100. Once installed in system 100, the circuit 110 is communicably connected to the CPU 171 and/or other components of the system 100 via one or more communication paths 176. The circuit 110 can be either tightly integrated into the system 100 (e.g., directly mounted and/or soldered to a same system board as the CPU 171), or it can be part of a peripheral module that is removably connected to the system board via a cable or connector. In some examples, the circuit 110 is part of an IC package that is distinct from the CPU 171. In other examples, circuit 110 is part of a same IC package (e.g., system-on-chip (SoC)) as the CPU 171.

FIG. 1B shows a case in which the hardware accelerator that comprises the circuit 110 is a peripheral hardware accelerator module 101 (“module 101”), shown in an uninstalled state separate from an information processing system. This peripheral hardware accelerator module 101 is separate from and removably connectable to a system board of an information processing system (such as system 100). The peripheral hardware accelerator module 101 may include a module printed circuit assembly (PCA) 102 which includes a printed circuit board (PCB) 103, the circuit 110 mounted to the PCB 102, and one or more connectors 104 formed in or mounted to the PCB 103. The connectors 104 may include one or more connectors for data communication, which communicably connected the module 101 to a system board of an information processing system (such as system 100) by mating with either an expansion slot connector on the system board or a connector of a cable, which is in turn coupled to a connector on the system board. This connection allows for exchange of data communication signals between circuit 110 and components of the system (e.g., CPU 171). Any desired communication protocol may be used, such as PCIe, Compute Express Link (CXL), Infiniband, etc. In some examples, the connectors 104 may also include power connectors to provide power to the module 101, in addition to or in lieu of supplying power through the data connectors. Module 101 may also include various other components, such as a chassis, housing, or bulkhead that provides structure support and facilitates installation in a system, networking interfaces, cooling components (heatsinks, fans, etc.), or other components.

In some examples, module 101 is specialized primarily in the computation of the interactions, as performed by circuit 110, and it is expected that external components (such as CPU 171) will perform additional processing using the interactions computed by the circuit 110. Thus, in such examples, module 101 does not necessarily comprise much other circuitry besides the circuit 110 and associated circuitry that supports the circuit 110.

In other examples, module 101 may perform multiple functions in addition to the interaction computations performed by the circuit 110. In such examples, the module 101 may include additional ICs (not illustrated) and/or other circuitry to perform these other functions. For instance, the module 101 may be a hardware accelerator for solving a particular type of problem, such as a high order HNN, a PUBO solver, a WalkSAT/SKC solver, etc. In such an example, the computation of the interactions between variables may be one important part of an algorithm implemented by the module 101 for solving the problem, but the module 101 may also include other components to perform other aspects of the algorithm, such as one or more microprocessors or other circuits to process the interactions calculated by the circuit 110 and make determinations based therein. As another example, module 101 may be a hardware accelerator with a wide suite of acceleration capabilities not necessarily limited to solving one particular type of problem, such as a graphics processing unit (GPU), tensor processing unit (TPU), data processing unit (DPU), or other accelerator, in which case module 101 may include various other components besides circuit 110.

In some examples, interaction computation circuit 110 may comprise a single IC. In some examples, interaction computation circuit 110 may comprise a multi-chip module, which comprises multiple ICs that are mounted to a common substrate, which may appear and act as if it were a single IC. Both the single IC and the multi-chip module may be referred to herein as an IC package. The IC package that comprises the circuit 110 may be mounted to the system board of an information processing system (e.g., system 100) or to a PCB of a peripheral module (e.g., PCB 103 of module 101).

### II. Example of Interaction Computation Circuit for a Polynomial Function

Turning to FIGS. 2A-2D, an interaction computation circuit 210 configured for computing interactions of variables of a polynomial function is illustrated. The circuit 210 is an example of the circuit 110. As an example of the circuit 110, the circuit 210 includes certain components which are the same as components of circuit 110 described above, and these elements are given the same reference numbers in relation to circuit 210 as were used above in relation to circuit 110. FIG. 2A shows a forward pass, FIG. 2B shows a backward break pass. FIG. 2C shows a backward make pass.

To illustrate operation of the circuit 210, it is assumed in FIGS. 2A-2D and the description below that the array(s) 220 encode the polynomial function H=a₁x₁+a₂x₁x₂+a₃x₁x₂x₃+a₄x₁x₂x₃x₄. However, it should be understood that other functions could be encoded and the same principles as discussed herein would apply.

As shown in FIG. 2A, the peripheral circuitry 230 includes a forward pass driver 231. The forward pass driver 231 receives input values for the variables x₁, . . . , x₄. To illustrate operation of the circuit 210, it is assumed in FIGS. 2A-2D and the description below that, the input values are [x₁, x₂, x₃, x₄]=[1,0,1,0]. However, it should be understood that other input values could be provided and the same principles as discussed herein would apply.

The forward pass driver 231 generates voltages Vₓᵢ based on the input values for variables xᵢ and applies them to the wires 122. Specifically, the forward pass driver generates the input voltages such that Vₓᵢ=V₀xᵢ. This may be equivalent to converting the digital values xᵢ into analog form, with digital 1 being converted to an analog V₀. Concurrently, the ground voltage is applied to term lines 122. As a result of the applications of these voltages, each term wire 122j receives an output current

$${I}_{t j} = {I}_{0} {\sum }_{j}^{term} = {I}_{0} {\sum }_{i} {b}_{i j} {x}_{i} .$$

The foregoing will be further illustrated by considering the particular function H and the input values [x₁, x₂, x₃, x₄]=[1,0,1,0] mentioned above and shown in FIGS. 2A-2C as an example. Given these inputs, the input voltages will be Vₓ₁=V₀, Vₓ₂=0, Vₓ₃=V₀, and Vₓ₄=0, which results in the output currents Iₜ₁=I₀, Iₜ₂=I₀, I₃=2I₀, and Iₜ₄=2I₀, as shown in FIG. 2A. Note also that in this case:

$${\sum }_{1}^{term} = {\sum }_{i} {b}_{i , 1} {x}_{i} = {x}_{i} = 1 ; {\sum }_{2}^{term} = {\sum }_{i} {b}_{i , 2} {x}_{i} = {x}_{1} + {x}_{2} = 1 ; {\sum }_{3}^{term} = {\sum }_{i} {b}_{i , 3} {x}_{i} = {x}_{1} + {x}_{2} + {x}_{3} = 2 ; and {\sum }_{4}^{term} = {\sum }_{i} {b}_{i , 4} {x}_{i} = {x}_{1} + {x}_{2} + {x}_{3} + {x}_{4} = 2.$$

In the circuit 210, the peripheral circuitry 230 further includes make/break term identification circuitry 232 which identifies make and break terms based on the output currents IJ. Circuitry 232 may first sense the output currents Iₜⱼ through current sensors, such as transimpedance amplifiers (not illustrated). Note that the sensing of the output current Iₜⱼ may result in the production of another signal that represents the current, such as an analog voltage or a digital value, but to simplify the description the signal that represents the sensed current Iₜⱼ in the circuitry 232 will be referred to herein as the current Iₜj.

For each term tⱼ, the make/break term identification circuitry 232 determines if the corresponding value

$${\sum }_{j}^{term}$$

is equal to the order (degree) Kⱼ of the term. If

$${\sum }_{j}^{term} = {K}_{j} ,$$

then the term tⱼ is identified as a break term. A break parameter zⱼ is used to indicate if a term tⱼ is a break term, with zⱼ=1 indicating the term tⱼ is a break term and zⱼ=0 indicating the term tⱼ is a not break term. It is not possible for a term to be both a make term and a break term (i.e., sⱼ and zⱼ cannot both equal 1), and therefore if tⱼ is identified as a break term (zⱼ=1) then this implies that tⱼ is not a make term (sⱼ=0).

Similarly, the make/k term identification circuitry 232 determines for each term tᵢ if the corresponding value

$${\sum }_{j}^{term}$$

is equal to Kⱼ−1. If

$${\sum }_{j}^{term} = {K}_{j} - 1$$

then the term tⱼ is identified as a make term. A make parameter s, is used to indicate if a term tⱼ is a make term, with sⱼ=1 indicating the term tⱼ is a make term and zⱼ=0 indicating the term tⱼ is a not make term. If tⱼ is identified as a make term (sⱼ=1) then this implies that tⱼ is not a break term (zⱼ=0).

Note that it is possible for a term tⱼ to be neither a make term nor a break term, in which case both sⱼ and zⱼ would equal 0.

Note that the values

$${\sum }_{j}^{term}$$

that are used in the comparisons described above come from the output currents Iₜj. Recall that each output current

$${I}_{t j} = {I}_{0} {\sum }_{j}^{term} .$$

Thus, each output current Iₜⱼ may be regarded as an analog representation of the digital value

$${\sum }_{j}^{term}$$

term I₀ being a digital/analog conversion factor (i.e., analog I₀ is equal to digital one). Thus, in some cases, analog to digital conversion of the signal representing the sensed output current Iᵢⱼ may occur before the determination of the make/break parameters is performed, in which case the term I₀ becomes one and drops out of the expressions. Thus, the determination of whether

$${\sum }_{j}^{term} = {K}_{j} or {\sum }_{j}^{term} = {K}_{j} - 1$$

can be rephrased as determining whether a digital representation of the output current Iₜⱼ is equal to Kⱼ or to Kⱼ−1.

In some examples, sⱼ and zⱼ are digital values which may be stored in flip-flops, latches, registers, or other similar digital logic storage elements. In some examples, the calculation in make/break term identification circuitry 232 of sⱼ and zⱼ is performed by digital logic circuits and/or by general purpose processor executing machine readable instructions, in which case the currents read from the term lines 122 may first be converted from analog to digital form to enable the digital processing. In this conversion, I₀ may be regarded as being equal to 1, and therefore in the equations for make/break determination above the conversion of the analog signal Iₜⱼ into digital form may is reflected in the term Iₜⱼ/I₀.

The operation of the make/break term identification circuitry 232 will be further illustrated by considering the function H (defined above) and the input values [x₁, x₂, x₃, x₄]-[1,0,1,0] as an example. Given these inputs, the term t₁ will be identified as a break term (z₁=1, s₁=0) because the output current

$${I}_{t 1} / {I}_{0} = {\sum }_{1}^{term} = 1$$

and the order of term t₁ is K₁=1, so

$${\sum }_{1}^{term} = {K}_{1} .$$

The term t₂ will be identified as a make term (z₂=0, s₂=1) because the output current

$${I}_{t 2} / {I}_{0} = {\sum }_{2}^{term} = 1$$

and the order of term t₂ is K₂=2, so

$${\sum }_{2}^{term} = {K}_{2} - 1.$$

The term t₃ will be identified as a make term (z₃=0, s₃=1) because the output current

$${I}_{t 3} / {I}_{0} = {\sum }_{3}^{term} = 2$$

and the order of term t₃ is K₃₌3, so

$${\sum }_{3}^{term} = {K}_{3} - 1.$$

Finally, the term t₄ will be identified as neither a make term nor a break term (z₄=0, s₄=0) because the output current

$${I}_{t 4} / {I}_{0} = {\sum }_{4}^{term} = 2$$

and the order of term t₄ is K₄=4, so

$${\sum }_{1}^{term}$$

term does not equal K₄ or K₄−1.

Next, a backward break pass may be performed based on the break value parameters zⱼ calculated in the forward pass, as illustrated in FIG. 2B. In this example, the peripheral circuitry 230 further includes break-pass driver 233, which generates the input voltages Vₜⱼ^{break} to apply to the term wires 122ⱼ based on the break value parameters zⱼ and the coefficients aⱼ of the terms tⱼ. Specifically, the break-pass driver 233 may include multiplication circuitry 234 for each term line 122ⱼ, and each of these is configured to multiply the break value parameter zⱼ of the corresponding term tⱼ with the coefficient aⱼ of the corresponding term tⱼ and output the result, converted to analog form, as input voltage Vₜⱼ^{break}=V₀·aⱼ·zⱼ to the corresponding term line 122ⱼ. Note that the V₀ appears in the expression of Vₜⱼ^{break} due to the digital to analog conversion, with analog voltage V₀ being equivalent to digital 1.

The digital-to-analog conversion may occur at any convenient point in the calculation. For instance, the digital value zⱼ may first be converted to an analog signal and then may be multiplied with an analog representation of aⱼ through analog multiplication circuitry. Or the digital value zⱼ may first be multiplied with a digital representation of aⱼ through digital multiplication circuitry and the resulting digital value may then be converted to analog form. In either case, the resulting input voltage is an analog signal Vₜⱼ^{break}=V₀·aⱼ·zⱼ.

This will be further illustrated by considering the example of the function H and the input values [x₁, x₂, x₃, x₄]=[1,0,1,0] and the resulting values of z₁=1, z₂=0, z₃=0, and z₄=0, as described above. Given these inputs, the input voltage Vₜ₁^{break} applied to term wire 122₁ is a₁V₀, and the input voltages Vₜ₂^{break}, Vₜ₃^{break} and Vₜ₄^{break} applied to the remaining wires 122₂, 122₃, and 122₄ are each equal to 0V, as shown in FIG. 2B. This results in output current Iₓ₁^{break} received on variable wire 122₁ equal to a₁I₀, and the output currents Iₓ₂^{break}, Iₓ₃^{break}, and Iₓ₄^{break} applied to the remaining wires 121₂, 121₃, and 121₄ are each equal to 0.

In the circuit 210, the peripheral circuitry 230 further includes break-pass output circuitry 235 as shown in FIG. 2B. Break-pass output circuitry 235 may sense the output currents Iₓᵢ^{break} through current sensors, such as transimpedance amplifiers (not illustrated). Note that the sensing of the output current Iₓᵢ^{break} may result in the production of another signal that represents the current, such as an analog voltage or a digital value, but to simplify the description the signal that represents the sensed current Iₓᵢ^{break} in the output circuitry 235 will be referred to herein as the current Iₓᵢ^{break}.

Break-pass output circuitry 235 further includes multiplication circuits 236a for each variable wire 121. The multiplication circuit 236a for a given variable wire 121ᵢ multiplies the sensed current Iₓᵢ^{break} by the value of the corresponding variable xᵢ. Thus, the multiplication circuit 236aⱼ outputs a value corresponding to xᵢIₓᵢ^{break}, which corresponds to the break value breakₓᵢ for the variable xi.

At some point in the above-described output path of output circuitry 235, the values may be converted from analog form to digital form, with the conversion factor being such that I₀ (or a voltage representation thereof) is equal to one. This analog to digital conversion may occur as part of the current sensing, after the current sensing but before the multiplication circuits 236a, or after the multiplication circuits 236a. As noted above, the output current Iₓᵢ^{break} prior to analog to digital conversion equals I₀ Σⱼ aⱼbᵢⱼzⱼ. Once analog to digital conversion has been performed, the term I₀ becomes equal to 1, and therefore the break values breakₓᵢ in digital form are given by

$${break}_{xi} = {x}_{i} {\sum }_{i}^{break} = {x}_{i} {\sum }_{j} {a}_{j} {b}_{i j} {z}_{j} .$$

In FIG. 2B, the conversion occurs after the multiplication circuits 236a, and therefore analog to digital converters (ADC)s 240a are shown positioned downstream of the multiplication circuits 236a. In this case, each ADC 240a converts an analog value XᵢIₓᵢ^{break} (or an analog voltage representing this value) as output from a corresponding multiplication circuit 236a into digital form. In such examples, the output of the ADC 240aⱼ is the digital representation of the break value breakₓᵢ for the variable xi. In this case, the multiplication circuits 236a perform analog multiplication, multiplying the analog signal representing the sensed current Iₓᵢ^{break} with an analog signal representing the variable xᵢ.

In other examples where ADC occur before the multiplication circuits 236a, the multiplication circuits 236a may perform digital multiplication. Then the output of the multiplication circuit 236aᵢ is the digital representation of the break value breakₓᵢ for the variable xᵢ.

This will be further illustrated by considering the example of the function H and the input values [x₁, x₂, x₃, x₄]=[1,0,1,0], and the input voltages of Vₜ₁^{break}=a₁V₀, Vₜ₂^{break}=0, Vₜ₃^{break}=0, and Vₜ₄^{break}=0, as described above. In this case, the output of the multiplication circuit 236a for wire 121₁ is a₁I₀, which is then converted by ADC 240a into the break value break x₁=a₁. For all of the other wires 121₂ to 121₄, their output current is zero and therefore the corresponding break values breakₓ₂, breakₓ₃, and breakₓ₄ are each equal to zero.

Next, a backward make pass may be performed based on the make value parameters sⱼ calculated in the forward pass, as illustrated in FIG. 2C. This backward make pass may be similar to the backward break pass except for using the make value parameters s, instead of the break value parameters zⱼ and also in that the complement of the variables are multiplied by the output currents in the output circuitry, rather than the variables themselves.

In particular, as shown in FIG. 2C, the peripheral circuitry 230 further includes make-pass driver 237, which generates the input voltages Vₜⱼ^{make} to apply to the term wires 122ⱼ based on the make value parameters s, and the coefficients aⱼ of the terms tⱼ. Specifically, the make-pass driver 237 may include multiplication circuitry 238 for each term line 122ⱼ, and each of these is configured to multiply the make value parameter sⱼ of the corresponding term tⱼ with the coefficient aⱼ of the corresponding term tⱼ and then output an input voltage Vₜⱼ^{make}=V₀ ·aⱼ·sⱼ to the corresponding term line 122ⱼ. This results in each variable wire 121, receiving an output current

$${I}_{xi} = {I}_{0} {\sum }_{i}^{m a k e} = {I}_{0} {\sum }_{j} {a}_{j} {b}_{ij} {s}_{j} .$$

This will be further illustrated by considering the example of the function H and the input values [x₁, x₂, x₃, x₄]=[1,0,1,0] and the resulting values of s₁=0, s₂=1, s₃=1, and s₄=0, as described above. In this case, the input voltage Vₜ₂^{make} applied to term wire 122₂ is a₂V₀, the input voltage Vₜ₃^{make} applied to term wire 122₃ is a₃V₀, and the input voltages Vₜᵢ^{make} and Vₜ₄^{make} applied to the remaining wires 122₁ and 122₄ are each equal to 0V, as shown in FIG. 2C. This results in output current Iₓ₂^{make} received on variable wire 122₂ equal to (a₂+a₃)I₀, the output current Iₓ₃^{make} received on variable wire 122₃ equal to a₃I₀, and the output currents Iₓ₁^{make} and Iₓ₄^{make} received on the remaining wires 121₁ and 121₄ are each equal to 0.

In the circuit 210, the peripheral circuitry 230 further includes make-pass output circuitry 239. Make-pass output circuitry 239 may sense the output currents Iₓᵢ^{make} through current sensors, such as transimpedance amplifiers (not illustrated). Note that the sensing of the output current Iₓ₁^{make} may result in the production of another signal that represents the current, such as an analog voltage or a digital value, but to simplify the description the signal that represents the sensed current Iₓᵢ^{make} in the output circuitry 239 will be referred to herein as the current Iₓᵢ^{make}.

Make-pass output circuitry 239 further includes multiplication circuits 236b for each variable wire 121. The multiplication circuit 236b for a given variable wire 121ᵢ multiples the output current Iₓᵢ^{make} by the value of the complement x of the corresponding variable xᵢ. Thus, the multiplication circuit 236aⱼ outputs a value corresponding to x̅_{ι}Iₓᵢ^{make} which corresponds to the make value makeₓᵢ for the variable xi.

As with the output circuitry 235, in the output circuitry 239 analog to digital conversion is performed at some point in the output path, and this may occur before or after the multiplication. The output current Iₓᵢ^{make} prior to analog to digital conversion equals I₀ Σⱼ aⱼbᵢⱼsⱼ. Once analog to digital conversion has been performed, the term I₀ becomes equal to 1, and therefore the make values makeₓᵢ in digital form are given by

$${make}_{xi} = \overline{{x}_{ι}} {\sum }_{i}^{m a k e} = \overline{{x}_{ι}} {\sum }_{j} {a}_{j} {b}_{i j} {s}_{j} .$$

In FIG. 3C, the analog to digital conversion is shown as occurring after the multiplication. In particular, in FIG. 3C the outputs of a multiplication circuit 236b is fed to a corresponding analog to digital converter (ADC) 240b, which converts the value to digital form and outputs the result as a make value makeₓᵢ for the variable xᵢ. Mathematically, the make value

$${make}_{xi} = {x}_{i} {\sum }_{i}^{m a k e} = \overline{{x}_{ι}} {\sum }_{j} {a}_{j} {b}_{i j} {s}_{j} .$$

This will be further illustrated by considering the example of the function H and the input values [x₁, x₂, x₃, x₄]=[1,0,1,0], and the input voltages of Vₜ₁^{make}=a₁V₀, Vₜ₂^{make}=0, Vₜ₃^{make}=0, and Vₜ₄^{make}=0, as described above. In this case, the output of the multiplication circuit 236a for wire 121₂ is (a₂+a₃)I₀, which is then converted by ADC 240a into the make value makeₓ₂=a₂+a₃, as shown in FIG. 2C. For the wire 121₃, the x̅₃̅ of the corresponding variable xi is equal to zero, and therefore the make value makeₓ₃ is equal to zero. For the wires 121₁ and 121₄, their output currents are zero, and therefore their corresponding make values makeₓ₂ and makeₓ₄ are each equal to zero.

In some examples, the peripheral circuitry 230 may further include a subtractor 241, as shown in FIG. 2D. This subtractor 241 is configured to subtract the make values makeₓᵢ from the corresponding break values breakₓᵢ. The results of this subtraction corresponds to the gradient of the function H, denoted ΔH. Specifically, the gradient ΔH may include a vector whose elements include the pseudo-partial derivatives of H with respect to each variable. The pseudo-partial derivatives of H with respect to variable xᵢ is denoted herein ΔHₓᵢ, which equals HₓᵢΔxᵢ, where Hₓᵢ is the difference quotient of H with respect to xᵢ and Axᵢ is the change in the variable value. In addition, HₓᵢΔx=breakₓᵢ−makeₓᵢ. Therefore, ΔH=[ΔHₓ₁, ΔHₓ₂, . . . , ΔHₓₙ]=[Hₓ₁Δx₁, Hₓ₂Δx₂, . . . , HₓₙΔₓₙ]=[breakₓ₁−makeₓ₁, breakₓ₂−makeₓ₂, . . . , breakₓₙ−makeₓₙ]. In other words, subtracting the make value from the break value for a single variable yields a pseudo partial derivative for that variable, and doing this for all of the variables and organizing the results as elements of a vector yields the gradient. This gradient ΔH may then be output from the circuit 210 as the computed interactions between the variables at the point corresponding to the input values for the variables. This may be used by subsequent processing, such as by solver logic 175, to determine next input values for another interaction.

### III. Example of Interaction Computation Circuit for a CNF Function

Turning to FIGS. 3A-2C, an interaction computation circuit 310 configured for computing interactions of variables of a CNF function is illustrated. The circuit 310 is an example of the circuit 110. As an example of the circuit 110, the circuit 310 includes certain components which are the same as components of circuit 110 described above, and these elements are given the same reference numbers in relation to circuit 310 as were used above in relation to circuit 110. FIG. 3A shows a forward pass, FIG. 3B shows a backward break pass. FIG. 3C shows a backward make pass.

To illustrate operation of the circuit 310, it is assumed in FIGS. 3A-3C and the description below that the array(s) 320 encode the CNF function CNF=(x̅₁̅∨x̅₂̅∨x₃ ∨x̅₄̅)∨(x̅₁̅·x₂), which is equivalent to the polynomial function H discussed above in relation to FIGS. 2A-2D. However, it should be understood that other functions could be encoded and the same principles as discussed herein would apply.

In this example, variable lines 121 are assigned to literals lᵢ. The literals lᵢ₌₂ₖ₋₁ correspond to the variables xₖ and are assigned to variable lines 121ᵢ₌₂ₖ₋₁, whereas the literals lᵢ₌₂ₖ correspond to complements x̅ₖ̅ and are assigned to variable lines 121ᵢ₌₂ₖ. Thus, literal l₁ is equal to variable xi and is assigned to variable line 121₁, literal l₂ is equal to complement x̅₁̅ and is assigned to variable line 121₂, literal l is equal to variable x₂ and is assigned to variable line 121₃, literal l₄ is equal to complement x̅₂̅ and is assigned to variable lines 121₄, and so on. FIG. 3A shows an example of such assignments of literals, variables, and complements to the variable lines 121 in the case of the function CNF with four variables xi to x₄.

As shown in FIG. 3A, the peripheral circuitry 330 includes a forward pass driver 331. The forward pass driver 231 receive input values for the variables x₁, . . . , x₄. To illustrate operation of the circuit 310, it is assumed in FIGS. 3A-3C and the description below that the input values are [x₁, x₂, x₃, x₄]=[1,0,1,0], which means that [l₁, l₂, l₃, l₄, l₅, l₆, l₇, l₈]=[1, 1, 0, 1, 1, 0, 0, 1]. Note that this is the same input values as where used in relation to FIGS. 2A-2D. However, it should be understood that other input values could be provided and the same principles as discussed herein would apply.

The forward pass driver 331 generates and voltage Vₗᵢ based on the input values and applied them to the wires 122ᵢ. Specifically, the forward pass driver generates the input voltage such that Vₗᵢ=V₀Iᵢ. This results in each term wire 122j receiving an output current

$${I}_{t j} = {I}_{0} {\sum }_{j}^{term} = {I}_{0} {\sum }_{i} {b}_{j i} {l}_{i} .$$

Given the function CNF and the input values [x₁, x₂, x₃, x₄]=[1,0,1,0] mentioned above, the input voltages will be Vₗ₁=V₀, Vₗ₂=0, Vₗ₃=V₀, and Vₗ₄=V₀, Vₗ₅=V₀, Vₗ₆=0, Vₗ₇=V₀, and Vₗ₈=V₀, which results in the output currents Iₜ₁=I₀ and Iₜ₂=0, as shown in FIG. 3A. Note also that in this case

$${\sum }_{1}^{term} = {\sum }_{i} {b}_{i , 1} {l}_{i} = \overline{{x}_{1}} + \overline{{x}_{2}} + \overline{{x}_{3}} + {x}_{4} = 1 and {\sum }_{2}^{term} = {\sum }_{i} {b}_{i , 2} {l}_{i} = \overline{{x}_{1}} + {x}_{2} = 0 .$$

In the circuit 310, the peripheral circuitry 330 further includes make/break term identification circuitry 332 which identifies make and break terms (clauses) based on the output currents Iₜⱼ. As described in relation to circuitry 232, circuitry 332 may include current sensors to sense the output currents Iₜⱼ. The make/break term identification circuitry 332 may use a slightly different algorithm for determining the make/break terms than the one used by the make/break term identification circuitry 232. For each term t₁, the peripheral circuitry 330 determines if

$${\sum }_{j}^{term}$$

is equal to one, zero, or something else. If

$${\sum }_{j}^{term} = 0 ,$$

then the term tⱼ is a make term and therefore sⱼ=1 and zⱼ=0. If

$${\sum }_{j}^{term} = 1 ,$$

then the term tⱼ is a break term and therefore sⱼ=1 and zⱼ=0. If

$${\sum }_{j}^{term}$$

is anything other than 0 or 1, then the term t₁ is neither a make term nor a break term and therefore both sⱼ=0 and zⱼ=0. As discussed above in relation to circuitry 232, analog to digital conversion may be performed on the sensed output currents Iₜ to obtain the values

$${\sum }_{j}^{term} .$$

This will be further illustrated by considering the example of the function CNF and the input values [xᵢ, x₂, x₃, x₄]=[1,0,1,0], as described above. Given these inputs, the term t₁ will be identified as a break term (z₁=1, s₁=0) because

$${I}_{t 1} / {I}_{0} = {\sum }_{1}^{term} = 1.$$

The term t₂ will be identified as a make term (z₂=0, s₂=1) because the output current

$${I}_{t 2} / {I}_{0} = {\sum }_{2}^{term} = 0.$$

In some examples, the output currents Iₜ can also be used to determine whether an optimization/convergence criterion of an optimization algorithm is satisfied. For instance, in some SAT algorithms, the optimization/convergence criterion is satisfied if each of the clauses of the CNF function are satisfied (true). It can be observed that, thanks to the manner in which the CNF function is encoded in the array 320, the output currents IJ encode this information: if Iₜⱼ=1, then clause tⱼ is satisfied, whereas if Iₜⱼ=0, then clause tⱼ is not satisfied. Thus, if Iₜⱼ=0 for all j, then the optimization/convergence criteria may be deemed met, whereas if Iₜ=0 for any j, then the optimization/convergence criteria may be deemed not met. Equivalently, if zₜⱼ=1 for all j, then the optimization/convergence criteria may be deemed met, whereas if zⱼ=0 for any j, then the optimization/convergence criteria may be deemed not met. The peripheral circuit 330 may notify external circuitry running the optimization algorithm, such as solver logic 175, as to whether the optimization criterion is met. In some examples, if the optimization criterion is met, then further performances of the backward passes can be omitted, but if the optimization criteria is deemed not met, then the peripheral circuitry 330 may move on to performing backward passes.

Next, a backward break pass may be performed based on the break value parameters zⱼ calculated in the forward pass, as illustrated in FIG. 3B. In this example, the peripheral circuitry 330 further includes break-pass driver 333, which generates the input voltages Vₜⱼ^{break} to apply to the term wires 122ⱼ based on the break value parameters zⱼ of the terms tⱼ. Specifically, the break-pass driver 333 is configured to convert the break value parameter zⱼ of the corresponding term t₁ into an analog input voltage Vₜⱼ^{break}, with the conversion setting digital 1 equal to V₀ and digital 0 equal to 0V. This can be expressed mathematically as Vₜⱼ^{break}=V₀·zⱼ. (Note that, unlike the break-pass driver 233 which is configured for a polynomial function, with the break-pass driver 333 coefficients aⱼ do not influence Vₜⱼ^{break}). When the voltages Vₜⱼ^{break} are applied to the term wires 122ⱼ, respectively, this results in each variable wire 121, receiving an output current

$${I}_{xi} = {I}_{0} {\sum }_{i}^{break} = {I}_{0} {\sum }_{j} {b}_{ij} {z}_{j} .$$

The operation of break-pass driver 333 be further illustrated by considering the example of the function CNF and the input values [xi, x₂, x₃, x₄]=[1,0,1,0], and the resulting values z₁=1 and z₂=0, as described above. In this case, the input voltage Vₜ₁^{break} applied to term wire 122₁ is V₀, and the input voltage Vₜ₂^{break} applied to the wire 122₂ is equal to 0V. This results in output currents Iₗ₁^{break}=0, Iₗ₂^{break}=0, Iₗ₃^{break}=0, Iₗ₄^{break}=0, Iₗ₅^{break}=0, Iₗ₆^{break}=I₀, Iₗ₇^{break}=I₀, and Iₗ₈^{break}=0 being applied to the wires 121₁-121₈, respectively, as shown in FIG. 3B.

In the circuit 310, the peripheral circuitry 330 further includes break-pass output circuitry 335. Break-pass output circuitry 335 may sense the output currents Iₗᵢ^{break} through current sensors, such as transimpedance amplifiers (not illustrated). Note that the sensing of the output current Iₗᵢ^{break} may result in the production of another signal that represents the current, such as an analog voltage or a digital value, but to simplify the description the signal that represents the sensed current Iₗᵢ^{break} in the output circuitry 335 will be referred to herein as the current Iₗᵢ^{break}.

Break-pass output circuitry 335 includes multiplication circuits 342 for each variable wire 121. The multiplication circuit 342 for a given variable wire 121ᵢ multiples the output current Iₗᵢ^{break} by the value of the corresponding literal lᵢ.

The break-pass output circuitry 335 further includes a number of adders 343aₖ each corresponding to one of the variables xₖ (which is also the literal lᵢ₌₂ₖ₋₁). In particular, adder 343a₁ corresponds to x₁, adder 343a₂ corresponds to x₂, adder 343a₃ corresponds to x₃, and so on. Each adder 343a receives and sums the outputs of the multiplication circuit 342 for the corresponding variable xₖ (literal lᵢ₌₂ₖ₋₁) and the multiplication circuit 342 for the complement x̅ₖ̅ (literal lᵢ₌₂ₖ) of the corresponding variable. Specifically, adder 343a₁ receives and sums the outputs of the multiplication circuits 342 for x₁ and x̅₁̅ (i.e., literals l₁ and l₂), the adder 343a₂ receives and sums the outputs of the multiplication circuits 342 for x₂ and x̅₂̅ (i.e., literals l₃ and l₄) the adder 343a₃ receives and sums the outputs of the multiplication circuits 342 for x₃ and x̅₃̅ (literals l₅ and l₆), and so on.

The break-pass output circuitry 335 further includes analog to digital converters (ADC) 344a. These may convert the signals from analog to digital at some point in the output chain. In FIG. 3B, the ADCs 344a are shown as being a last link in the output chain, such that the multiplication and addition performed by the circuits 342a and adders 343a is analog multiplication and analog addition. In this case, each ADC 344aₖ corresponds to one of the variables xₖ and receives the output of one of the adders 343a which is connected (through a multiplication circuit 343b) to the variable line 121ᵢ₌₂ₖ₋₁ of the corresponding variable xₖ. The ADC 344a converts the received value to digital form, with the result being output as a break value breakₓₖ for the corresponding variable xₖ. Specifically, ADC 344a₁ receives the output of adder 343ai and outputs breakₓ₁, ADC 344a₂ receives the output of adder 343a₂ and outputs breakₓ₂, and so on. In other examples, the ADCs 344a could be placed elsewhere in the chain. For instance, the output currents Iₗᵢ^{break} could first be converted into digital values and then the multiplication and addition of circuits 342 and adders 343a could be digital arithmetic, in which case the output of adders 343a may be equal to the break values breakₓₖ. Regardless of where the ADC takes place, ultimately the resulting break values may be equal to

$${break}_{xk} = {x}_{k} {\sum }_{i = 2 k - 1}^{break} + \overline{{x}_{k}} {\sum }_{i = 2 k}^{break} = {x}_{k} {\sum }_{j} {b}_{2 k - 1 , j} {z}_{j} + \overline{{x}_{k}} {\sum }_{j} {b}_{2 k , j} {z}_{j} .$$

The operation of break-pass output circuitry 335 may be further illustrated by considering function CNF and the input values [x₁, x₂, x₃, x₄]=[1,0,1,0], and the resulting output currents Iₗᵢ^{break}=0, Iₗ₁^{break}=I₀, Iₗ₃^{break}=0, Iₗ₄^{break}=I₀, Iₗ₅^{break}=0, Iₗ₆^{break}=i₀, iₗ₇^{break}=I₀, and iₗ₈^{break}=0, as described above. In this case, the output of the multiplication circuits 342 for l₃ and l₄ are 0 and I₀, respectively, resulting in an output of I₀ from the corresponding adder 343a₂, resulting in a break value for the variable x₂ of breakₓ₂=1. For all of the other multiplication circuits 342, their outputs are zero, either because an input current of zero was input thereto or because the value of the corresponding literals was zero. Consequently, the break values breakₓ₂, breakₓ₃, and breakₓ₄ are each equal to zero.

Next, a backward make pass may be performed based on the make value parameters sⱼ calculated in the forward pass, as illustrated in FIG. 3C. This backward make pass may be similar to the backward break pass except for using the make value parameters s, instead of the break value parameters zⱼ and also in that the complement of the literals are multiplied by the output currents in the output circuitry, rather than the literals themselves.

In particular, the peripheral circuitry 330 further includes make-pass driver 337, which generates the input voltages Vₜⱼ^{make} to apply to the term wires 122, based on the make value parameters sⱼ of the terms tⱼ. Specifically, the make-pass driver 333 is configured to convert the make value parameter sⱼ of the corresponding term tⱼ into an analog input voltage Vₜⱼ^{make}, with the conversion setting digital 1 equal to V₀ and digital 0 equal to 0V. This can be expressed mathematically as Vₜⱼ^{make}=V₀ ∜sⱼ. (Note that, unlike the make-pass driver 233 which is configured for a polynomial function, with the make-pass driver 333 coefficients aⱼ do not influence Vₜⱼ^{make}). When the voltages Vₜⱼ^{make} are applied to the term wires 122ⱼ, respectively, this results in each variable wire 121ᵢ receiving an output current

$${I}_{li} = {I}_{0} {\sum }_{i}^{make} = {I}_{0} {\sum }_{j} {b}_{ij} {z}_{j} .$$

The operation of make-pass driver 333 be further illustrated by considering the example of the function CNF and the input values [x₁, x₂, x₃, x₄]=[1,0,1,0], and the resulting values s₁=0 and s₂=1, as described above. In this case, the input voltage Vₜ₁^{make} applied to term wire 122₁ is 0V and the input voltage Vₜ₂^{make} applied to the wire 122₂ is equal to V₀. This results in output currents Iₗ₁^{make}=0, Iₗ₂^{make}=I₀, Iₗ₃^{make}=0, Iₗ₄^{make}=0, Iₗ₅^{make}=0, Iₗ₆^{make}=₀, Iₗ₇^{make=}₀, and Iₗ₈^{make}=0 being applied to the wires 121₁-121₈, respectively, as shown in FIG. 3C.

In the circuit 310, the peripheral circuitry 330 further includes make-pass output circuitry 339. Make-pass output circuitry 339 may sense the output currents Iₗᵢ^{make} through current sensors, such as transimpedance amplifiers (not illustrated). Note that the sensing of the output current Iₗᵢ^{make} may result in the production of another signal that represents the current, such as an analog voltage or a digital value, but to simplify the description the signal that represents the sensed current Iₗᵢ^{make} in the output circuitry 339 will be referred to herein as the current Iₗᵢ^{make}.

Make-pass output circuitry 339 includes multiplication circuits 345 for each variable wire 121. The multiplication circuit 345 for a given variable wire 121, multiples the output current Iₗᵢ^{make} by the value of the complement l̅ᵢ̅ of the corresponding literal lⱼ. Thus, the multiplication circuit 345 for the wire 121₁ multiplies the current Iₗ₁^{make} with the value of l̅₁̅ which is equal to x̅₁̅, the multiplication circuit 345 for the wire 121₂ multiplies the current Iₗ₂^{make} with the value of l̅₂̅ which is equal to x₁, the multiplication circuit 345 for the wire 121₃ multiplies the current Iₗ₃^{make} with the value of l̅₃̅ which is equal to x̅₂̅, the multiplication circuit 345 for the wire 121₄ multiplies the current Iₗ₄^{make} with the value of l̅₄̅ which is equal to x₂, and so on.

The make-pass output circuitry 335 further includes a number of adders 343b. Each adder 343bₖ corresponds to one of the variables xk, and receives and sums the outputs from the multiplication circuits 345 associated with the complement of the literals l̅=̅ₗ̅₌̅₂̅ₖ̅₋̅₁̅ and l=ₗ₌₂ₖ. Specifically, the adder 343b₁ receives and sums the outputs of the multiplication circuits 345 for literal complements l̅₁̅ and l̅₂̅, the adder 343b₂ receives and sums the outputs of the multiplication circuits 345 for literal complements l̅₃̅ and l̅₄̅, the adder 343b₃ receives and sums the outputs of the multiplication circuits 345 for literal complements l̅₅̅ and l̅₆̅, and so on.

The make-pass output circuitry 335 further includes analog to digital converters (ADC) 344b. These may convert the signals from analog to digital at some point in the output chain. In FIG. 3C, the ADCs 344b are shown as being a last link in the output chain, such that the multiplication and addition performed by the circuits 345 and adders 343b is analog multiplication and analog addition. In this case, each ADC 344bₖ corresponds to one of the variables xₖ and receives the output of one of the adders 343bₖ for corresponding to the same variable xₖ. The ADC 344bₖ converts the received value to digital form, with the result being output as a make value makeₓₖ for the corresponding variable xₖ. In other examples, the ADCs 344b could be placed elsewhere in the chain. For instance, the output currents I₁ make could first be converted into digital values and then the multiplication and addition of circuits 342b and adders 343b could be digital arithmetic, in which case the output of adders 343b may be equal to the make values makeₓₖ. Regardless of where the ADC takes place, ultimately the resulting make values may be equal to

$${make}_{xk} = \overline{{l}_{2 k - 1}} {\sum }_{2 k - 1}^{make} + \overline{{l}_{2 k}} {\sum }_{2 k}^{make} = \overline{{l}_{k - 1}} {\sum }_{j} {b}_{2 k - 1 , j} {s}_{j} + \overline{{l}_{2 k}} {\sum }_{j} {b}_{2 k , j} {s}_{j} .$$

The operation of make-pass output circuitry 339 may be further illustrated by considering function CNF and the input values [x₁, x₂, x₃, x₄]=[1,0,1,0], and the resulting output currents Iₗ₁^{make}=0, Iₗ₂^{make}=I₀, Iₗ₃^{make}=0, Iₗ₄^{make}=0, Iₗ₅^{make}=0, Iₗ₆^{make}=0, Iₗ₇^{make}=0, and Iₗ₈^{make}=0, as described above. In this case, the output of the multiplication circuits 342 for l̅₁̅ and l̅₂̅ are 0 and I₀, respectively, resulting in an output of I₀ from the corresponding adder 343b₁, resulting in a make value for the variable x₁ of makeₓ₁=1. Furthermore, the output of the multiplication circuits 342 for l̅₃̅ and l̅₄̅ are I₀ and 0, respectively, resulting in an output of I₀ from the corresponding adder 343₂, resulting in a make value for the variable x₂ of makeₓ₂=1. For all of the other multiplication circuits 342, their outputs are zero, and consequently the make values makeₓ₃ and makeₓ₄ are each equal to zero.

In some examples, the make values and the break values calculated in the make and break passes are the interactions of interest, and these may be output from the circuit 310 to external circuits for further processing. In other examples, the circuit 310 may further process the make values and the break values to determine some other value, which is the interaction of interest. For instance, in some examples, the peripheral circuitry 330 may further include a subtractor (not illustrated) analogous to the subtractor 241, which is configured to subtract the break values breakₓₖ from the corresponding make values makeₓₖ, the result of which is a gain of the CNF function. Gain is a term used in the context of CNF for a value that is analogous to the gradient in the context of polynomials. Mathematically, the gain may be equal to a negative of the gradient. Herein, when the particular type of function under consideration is not specified, then the term “gradient” is to be understood broadly as including the gradient of a polynomial, a gain of a CNF function, or another analogous parameter, and is not limited specifically to the strict mathematical definition of a gradient of a function such as a polynomial function. The gain thus calculated may be used by subsequent processing, such as solver logic 175, to determine next input values for another interaction.

### IV. Additional Aspects of Examples of the Interaction Computation Circuit

In addition to the logic described above in relation to FIGS. 1-3C, the circuits 110, 210, and/or 310 may include various other components (not shown) which are common to the operation of many memory arrays, such as voltage sources for applying voltages to the wires 121 and 122, transimpedance amplifiers or other sensing circuits for sensing output currents, digital to analog converters or analog to digital converts, multiplexors, filters, amplifiers, buffers, etc. These components are understood by those of ordinary skill in the art and thus are not shown herein.

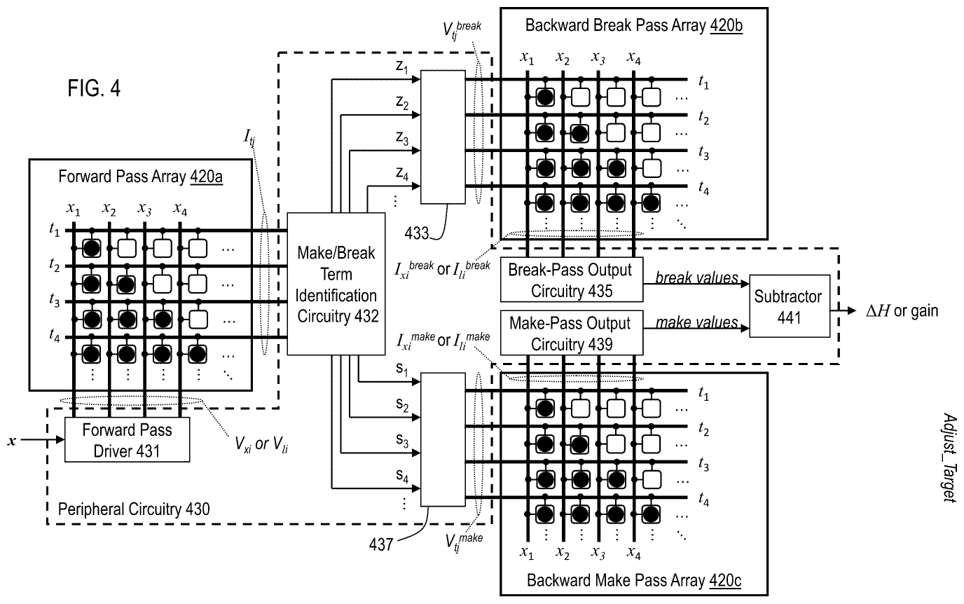

In some examples of the circuits 110, 210, and/or 310, different arrays 120, 320, or 420 may be used for each of the forward, backward break, and backward make passes, resulting in at least three arrays 120, 320, and 420 being present. FIG. 4 illustrates one such example, which will be described below.

In other examples of the circuits 110, 210, and/or 310, the backward make and break passes (such as are illustrated in FIGS. 2B and 2C or 3B and 3C) can be performed on the same array 110, 220, or 320. For instance, a first array 110, 220, or 320 may perform the forward pass and a second array 110, 220, or 320 may perform both the backward make pass and the backward break pass.

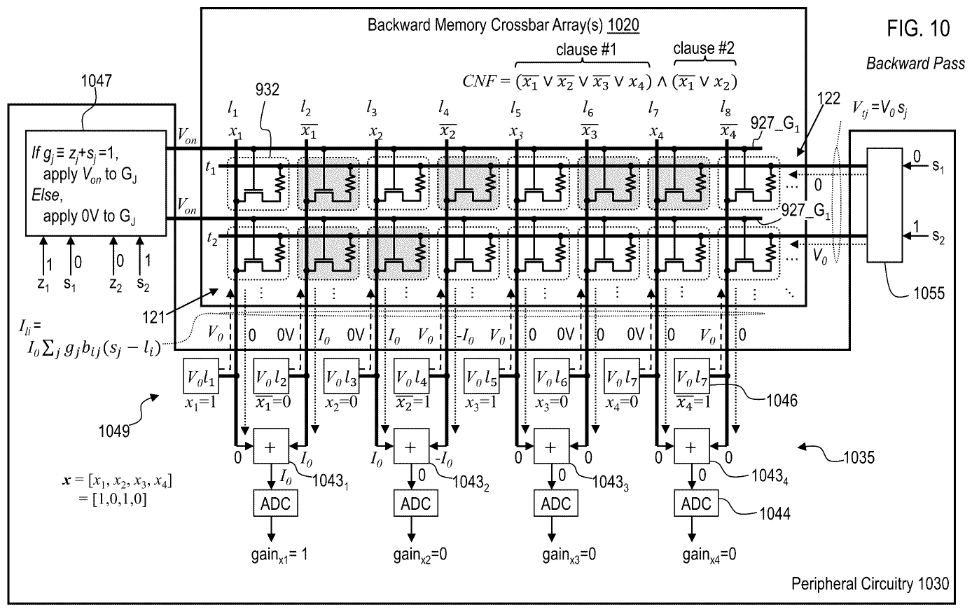

Or, in other examples of the circuits 110, 210, and/or 310, the forward pass, the backward make pass, and the backward break pass may all be performed on the same single array 110, 220, or 320. FIG. 10 illustrates one such example, which will be described below.

In examples where multiple passes are performed using the same array 110, 220, or 320, the peripheral circuitry 110, 230, or 330 may include multiplexors or other circuitry, as appropriate, to enable each of the wires 121 and 122 to connect to the appropriate circuits during the different passes, as described above. For instance, during the forward pass term wires 122 may need to connect to the make/break term identification circuitry 232 or 332, during a backward break pass the term wires 122 may need to connect to the break-pass driver 233 or 333, and during a backward make pass the term wires 122 may need to connect to make-pass driver 233 or 333, and multiplexors may be used to switch connections between the wires 122 and these circuits.

Furthermore, in some examples in which multiple passes are performed on the same array 120, 220, or 320, certain circuits which were described separately above in relation to the different passes could be consolidated into the same circuits, with appropriate modifications as would be apparent to one of ordinary skill in the art. For instance, if a break pass and a make pass are performed on the same array, then the break-pass driver 233 and the make-pass driver 237 described above could be consolidated into a single backward pass driver circuit that performs the functions of both of the aforementioned drivers 233 and 237. This may allow for some space efficiencies, such as by allowing a single set of multiplication circuits to perform the functions of both the circuits 234 and 238 (albeit with different inputs input thereto in the make and break passes).

Performing multiple passes on the same array can allow for reduced circuit size, and hence reduced cost and power usage, for the circuit 110, 210, and/or 310. On the other hand, performing multiple passes on the same array might also increase the complexity of the peripheral circuitry, which can also affect costs. Furthermore, in some cases, performing multiple passes on the same array might increase latency, i.e., the number of clock cycles that are required for a single iteration of processing to be completed. Thus, both approaches may be desirable under certain circumstances.

Although the circuits 210 and 310 which process polynomial and CNF functions, respectively, are described separately above, in some examples of the circuit 110 both polynomial and CNF functions can be processed. In other words, some examples of the circuit 110 may include logic corresponding to both that of the circuit 210 and that of the circuit 310, and the circuit may intelligently select which logic to employ depending on which type of function is to be processed. In such examples, components which perform similar functions in the circuits 210 and 310 can be consolidated into a single component that can perform either function. For instance, forward pass drivers 231 and 331 can be consolidated into a single forward pass driver that either applies the voltage V as described above to the variable wires 121, if a polynomial function is being processed or applies the voltages Vₗ as described above to the variable lines 121, if a CNF function is being processed. As another example, break pass driver 233 and break pass driver 333 could be consolidated into a single break pass driver that applies the voltages Vₜⱼ^{break}=V₀zⱼ aⱼ to the term wires 122, if a polynomial function is being processed or applies the voltages Vₜⱼ^{break}=V₀zⱼ to the term wires 122, (this could be accomplished, for instance, by modifying the logic of the break pass driver 233 so as to set aⱼ=1 for each j if the function is a CNF function).

In other examples of the circuit 110, the circuit 110 may be configured specifically to handle one type of function, such as a polynomial function or CNF function. This reduces the versatility of the circuit but might allow for it to be more efficient in terms of space (by omitting components not needed) or in terms of operation.

V. Example of Interaction Computation Circuit with Multiple Arrays

FIG. 4 illustrates an interaction computation circuit 410 that comprises multiple different arrays for forward and backward passes. Circuit 410 is an example implementation of circuits 110, 210, or 310. Note that references herein to different or separate memory arrays does not necessarily mean that the arrays are distinct components or chips, but rather means that the arrays comprise different groups of memory cells 130, which could be part of separate components/chips or which could be parts of different regions within the same component/chip.

Circuit 410 comprises a forward pass array 420a which performs the forward pass, a backward break pass array 420b which performs the backward break pass, and a backward make pass array 420c which performs the backward make pass. The arrays 420a, 420b, and 420c are example implementations of the arrays 120. Arrays 420a, 420b, and 420c may be programmed with a polynomial function, making them example implementations of the array(s) 220, or they may be programmed with a CNF function, making them example implementations of the array(s) 320.

Circuit 410 comprises peripheral circuitry 430, which is an example implementation of peripheral circuitry 130, 230, or 330. The peripheral circuitry 430 includes forward pass driver 431, which is an example of forward pass driver 231 and 331. Forward pass driver 431 receives an input assignment of values for the variables and generates forward pass input voltage to apply to the variable wires of forward pass array 420a, as described above in relation to forward pass drivers 231 and 331.

The peripheral circuitry 430 further includes make/break term identification circuitry 432, which is an example of make/break term identification circuitry 232 and 332. Make/break term identification circuitry 432 receives the output currents from forward pass array 420 and determines values for break parameters zⱼ and make parameters sⱼ. In some examples, circuit 410 is configured to process polynomial functions, in which case make/break term identification circuitry 432 may determine zⱼ and sⱼ in the manner described above in relation to make/break term identification circuitry 232. In some examples, circuit 410 is configured to process CNF functions, in which case make/break term identification circuitry 432 may determine zⱼ and sⱼ in the manner described above in relation to make/break term identification circuitry 332. In some examples, circuit 410 is capable of processing both polynomial and CNF functions, in which case make/break term identification circuitry 432 may be configured to be capable of determining zⱼ and sⱼ in both the manner described above in relation to make/break term identification circuitry 232 and the manner described above in relation to make/break term identification circuitry 332, with the make/break term identification circuitry 432 deciding which approach to use based on whether the function currently being processed is a polynomial function or CNF function.

The break parameters zⱼ are fed to break-pass driver 433, which is an example implementation of break-pass driver 233 or 333. Break-pass driver 433 generates input voltages Vₜⱼ^{break} to apply to the backward break pass array 420b based on the break parameters z₁. In some examples, circuit 410 is configured to process polynomial functions, in which case break-pass driver 433 may determine the input voltages Vₜⱼ^{break} in the manner described above in relation to break-pass driver 233. In some examples, circuit 410 is configured to process CNF functions, in which case break-pass driver 433 may determine the input voltages Vₜⱼ^{break} in the manner described above in relation to break-pass driver 333. In some examples, circuit 410 is capable of processing both polynomial and CNF functions, in which case break-pass driver 433 may be configured to be capable of determining the input voltages Vₜⱼ^{break} in both the manner described above in relation to break-pass driver 233 and the manner described above in relation to break-pass driver 333, with the break-pass driver 433 deciding which approach to use based on whether the function currently being processed is a polynomial function or CNF function. In some examples, the break-pass driver 233 can be converted to operate as the break-pass driver 333 by simply setting the coefficients aⱼ to all equal 1. Thus in some examples, break-pass driver 433 may be configured similarly to break-pass driver 233, except with the addition that break-pass driver 433 uses the regular coefficient values aⱼ if a polynomial function is being processed but uses coefficients aⱼ to all equal 1 if a CNF function is being processed.

Concurrently with the inputting of the parameters zⱼ to the driver 433, the make parameters s, are fed to make-pass driver 437, which is an example implementation of make-pass driver 237 or 373. Make-pass driver 437 generates input voltages Vₜⱼ^{make} to apply to the backward make pass array 420c based on the make parameters sⱼ. In some examples, circuit 410 is configured to process polynomial functions, in which case make-pass driver 437 may determine the input voltages Vₜⱼ^{make} in the manner described above in relation to make-pass driver 237. In some examples, circuit 410 is configured to process CNF functions, in which case make-pass driver 437 may determine the input voltages Vₜⱼ^{make} in the manner described above in relation to make-pass driver 373. In some examples, circuit 410 is capable of processing both polynomial and CNF functions, in which case make-pass driver 437 may be configured to be capable of determining the input voltages Vₜⱼ^{make} in both the manner described above in relation to make-pass driver 237 and the manner described above in relation to make-pass driver 373, with the make-pass driver 437 deciding which approach to use based on whether the function currently being processed is a polynomial function or CNF function. In some examples, the make-pass driver 237 can be converted to operate as the make-pass driver 337 by simply setting the coefficients aⱼ to all equal 1. Thus in some examples, make-pass driver 437 may be configured similarly to make-pass driver 237, except with the addition that make-pass driver 437 uses the regular coefficient values aⱼ if a polynomial function is being processed but uses coefficients aⱼ to all equal 1 if a CNF function is being processed.

The input voltages Vₜⱼ^{break} and Vₜⱼ^{make} are concurrently input from drivers 433 and 437 to the arrays 420b and 420c, respectively. This results in the backward break pass array 420b outputting currents Iₓᵢ^{break} from each variable wire to break-pass output circuitry 435. Concurrently, the backward make pass array 420c outputs currents Iₓᵢ^{make} from each variable wire to make-pass output circuitry 439.

Break-pass output circuitry 435 calculates break values based on the currents Iₓᵢ^{break}In some examples, circuit 410 is configured to process polynomial functions, in which case break-pass output circuitry 435 may determine the break values in the manner described above in relation to break-pass output circuitry 235. In some examples, circuit 410 is configured to process CNF functions, in which case break-pass output circuitry 435 may determine the break values in the manner described above in relation to break-pass output circuitry 335. In some examples, circuit 410 is capable of processing both polynomial and CNF functions, in which case break-pass output circuitry 435 may be configured to be capable of determining the break values in both the manner described above in relation to break-pass output circuitry 235 and the manner described above in relation to break-pass output circuitry 335, with the break-pass output circuitry 435 deciding which approach to use based on whether the function currently being processed is a polynomial function or CNF function.

Concurrently with the calculation of the break values, make-pass output circuitry 439 calculates make values based on the currents Iₓᵢ^{make} In some examples, circuit 410 is configured to process polynomial functions, in which case make-pass output circuitry 439 may determine the make values in the manner described above in relation to make-pass output circuitry 239. In some examples, circuit 410 is configured to process CNF functions, in which case make-pass output circuitry 439 may determine the make values in the manner described above in relation to make-pass output circuitry 339. In some examples, circuit 410 is capable of processing both polynomial and CNF functions, in which case make-pass output circuitry 439 may be configured to be capable of determining the make values in both the manner described above in relation to make-pass output circuitry 239 and the manner described above in relation to make-pass output circuitry 339, with the make-pass output circuitry 439 deciding which approach to use based on whether the function currently being processed is a polynomial function or CNF function.

In some examples, the break values and the make values may be fed to a subtractor 441, which either subtracts the make values from respectively corresponding break values, yielding a gradient (or negative of a gain), or subtracts the break values from respectively corresponding make values, yielding a gain (or negative of a gradient).

Using multiple arrays as is down in FIG. 4 results in a larger communication size for the memory arrays. However, this allows for faster processing, as break and make passes can be performed concurrently. If make and break passes are instead performed on the same array, then without additional special circuitry (described below) the passes would need to be performed one after the other, taking twice as long. Furthermore, performing the forward pass and the backward passes on different arrays allows for multiple threads to be run concurrently, with the forward pass of one thread being performed on array 420a at the same time that the backward passes for another thread are being performed on the arrays 420b and 420c. Thus, while each iteration in each thread still takes the same amount of time, the two threads are performed concurrently in a pipelined/interleaved fashion, allowing for twice the throughput.

VI. Example of Interaction Computation Circuit without Make Pass

In some examples, the interactions of interest may comprise just the break values, without any need to calculate the make values or gradient (gain). In such examples, the circuitry shown in FIG. 4 can be simplified by omitting the array 420, driver 437, and circuitry 439. Furthermore, in some examples, the circuitry can be even further simplified by altering circuitry 432 to compute only the break parameters and not the make parameters.

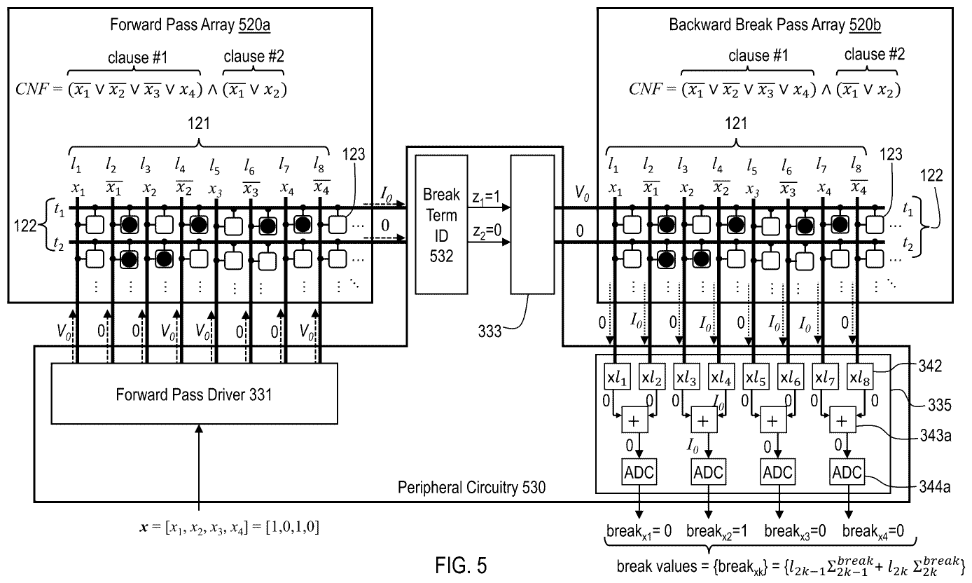

For instance, FIG. 5 illustrates a circuit 510, which is one example implementation of circuit 110 in which a CNF function is processed and in which break values are calculated but make values are not explicitly calculated.

Circuit 510 comprises a forward pass array 520a and a backward break pass array 520b. The arrays 520a and 520b are example implementations of the arrays 120. As an example, the CNF function described above is shown encoded into the arrays 520a and 520b.

The circuit 510 also comprises peripheral circuitry 530, which is an example of peripheral circuitry 130. The peripheral circuitry 530 may include forward pass driver 331, which may be identical to the forward pass driver 331 described above. peripheral circuitry 530 further includes a break term identification circuitry 532. The break term identification circuitry 532 corresponds to the make-break term identification circuitry 332 described above, except, in some examples, further modified to only compute the break parameters zⱼ and not the make parameters sⱼ. (In some examples, circuitry 532 may still compute make parameters sⱼ, but these might not be used in the backward pass). The peripheral circuitry 530 may include break pass driver 333, which may be identical to break pass driver 333 described above. The peripheral circuitry 530 may include break pass output circuitry 335, which may be identical to the break pass output circuitry 335 described above.

Peripheral circuitry 530 may drive the forward pass array 520a in a forward pass similar to that described above in relation to FIG. 3A, except for the omission of calculating make parameters sⱼ. Peripheral circuitry 530 may then drive the backward break pass array 520b in a backward break pass identical to that described above in relation to FIG. 3B. The break values output from break pass output circuitry 335 may then be fed as inputs to external circuitry, such as solver logic 175, for subsequent processing. For instance, solver logic 175 may implement an optimization algorithm that utilizes break values to determine a next iteration, such as a WalkSAT/SKC algorithm.

### VII. Example Memory Cell Architectures for Interaction Computation Circuit

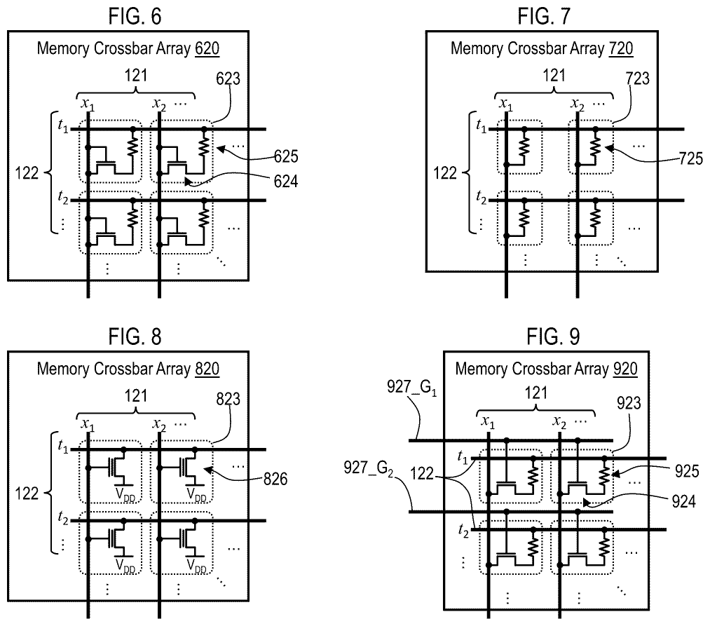

Turning now to FIGS. 6-9, some examples of architectures for memory cells 123 will be described.

FIG. 6 illustrates memory crossbar array 620, which is one example of the array 120. Array 620 includes memory cells 623, which are examples of the memory cells 123. Each memory cell 623 includes a memristor 625. A memristor is also sometimes called resistive random-access memory (ReRAM). As used herein, a memristor is a two terminal electrical component that has a variable and settable impedance (resistance) between the two terminals, or in other words, a variable conductance between the two terminals (conductance being the inverse of impedance), wherein the resistance/conductance can be changed by applying a setting or resetting signal (e.g., voltage) across the terminals and, once set, the resistance/conductance stays substantially at the set value unless changed by application of another setting or resetting signal. The setting/resetting signals may be voltages having sufficiently large magnitude to cause the resistance/conductance to change, with a polarity of the voltage dictating whether the resistance increases or decreases. If a read voltage is applied across the terminals (the read voltage being a voltage low enough to not substantially change the set resistance state), a current will flow between the terminals with the magnitude of the current being dependent on the current resistance (conductance) of the memristor depend on the resistance state thereof in accordance with Ohms law (i.e., current=voltage divided by resistance). This current can be sensed to determine the state of the memristor. Thus, the memristor can be used as a memory element which can store different values by setting the resistance (conductance) thereof to different levels, with these stored values being readable from the memory cell by applying a voltage across it, reading the resulting current flowing form the memory cell, and identifying the stored value based on the magnitude of the current. Specifically, the memristor can be placed in at least the Active and Inactive states described above by switching its resistance between a very high value, rendering it essentially non-conducting (Inactive state), and a lower value, rendering it conducting (Active state). In some examples, the memristor can be set to other states to store more than two values by setting its resistance to intermediate values.

In the example of FIG. 6, the memory cell 623 further comprises a transistor 624, and the transistor 624 and memristor 625 are coupled in series between the variable wire 121 and the term wire 122 corresponding to the particular cell 623. The transistor 624 has one terminal (source or drain) coupled to the variable line 121 and the other terminal (drain or source) coupled with the memristor 625, whereas the memristor has one terminal coupled to the transistor 624 and the other coupled to the term line 122. The gate of the translator 624 is also coupled to the variable line 121. Thus, if a positive voltage greater than the threshold voltage of the transistor 624, such as V₀, is applied to the variable line 121, the ground voltage is applied to the term line 122, and the memristor 625 is in the active state, then the transistor 624 will turn ON and current will flow from the variable line 121 to the term line 122 through the memristor 625, with the magnitude of the current dependent on the resistance of the memristor 625. On the other hand, if a voltage lower than the threshold voltage, such as the ground voltage, is applied to the variable line 121, then the transistor 624 will be turned off and no current will flow regardless of the state of the memristor 625. Or if the memristor is in the inactive state, then (substantially) no current will flow regardless of the state of the transistor 625. The purpose of the transistor 624 in cell 623 is to prevent leakage current.

Note that the memory cell 623 as shown is suitable for an array 620 performing a forward pass. The same memory cell architecture could be used in an array that is to perform a backward pass, but in that case the variable wires and term wires would be switched. In other words, in that case, the transistor would be coupled to the term wire, rather than the variable wire, and the memristor would be coupled to the variable wire, rather than the term wire.

FIG. 7 illustrates memory crossbar array 720, which is one example of the array 120. Array 720 includes memory cells 723, which are examples of the memory cells 123. Each memory cell 723 includes a memristor 725. The memristor 725 has one terminal connected to the variable wire 121 associated with the cell 723 and another terminal connected to the term wire 122 associated with the cell 723.

In this example, the current flowing through the cell 723 depends on the state of the memristor 725 and the magnitude and polarity of voltage applied across it. If the memristor 725 is in an inactive state, no current will flow regardless of the voltages applied, so long as the voltages remain within the reading range for the memristor 725 (larger magnitude voltage may cause the memristor 725 to change resistance, and thus are avoided except for when deliberately setting/resetting the memristor 725). If the memristor 725 is in the active state, a positive voltage is applied to variable wire 121, and a ground voltage is applied to term wire 122, then current will flow from the variable wire 121 to the term wire 122. If the memristor 725 is in the active state, a positive voltage is applied to the term wire 122, and a ground voltage is applied to the variable wire 121, then current will flow from the term wire 122 to the variable wire 121. If ground is applied to both variable and term wires 121 and 122, then no current will flow.

FIG. 8 illustrates memory crossbar array 820, which is one example of the array 120. Array 820 includes memory cells 823, which are examples of the memory cells 123. Each memory cell 823 includes a floating gate transistor 826 operating in a sub-threshold region. The floating gate transistor 826 has one terminal connected to a source of positive voltage, V_{DD}, and another terminal connected to the term wire 122 associated with the cell 823. Furthermore, a control gate of the floating gate transistor 826 is connected to the variable wire 121 associated with the cell 823.

In this example, the current flowing through the cell 823 depends on the state of the floating gate transistor 826 and the magnitude of voltages applied across it. If the floating gate transistor 826 is in an inactive (non-conductive) state, substantially no current will flow. If the floating gate transistor 826 is in the active state, a positive voltage is applied to variable wire 121, and a ground voltage is applied to term wire 122, then current will flow from the V_{DD} rail to the term wire 122, with the magnitude of the current dependent on the charge state of the floating gate of the floating gate transistor 826.

FIG. 9 illustrates memory crossbar array 920, which is one example of the array 120. Array 920 includes memory cells 923, which are examples of the memory cells 123. Each memory cell 923 includes a memristor 925 and a transistor 924 connected in series between the variable wire 121 and the term wire 123, similar to the memory cell 623. However, unlike in the cell 623, in the cell 923 the gate of the transistor 924 is coupled to a gate line 927 (e.g., 927_G₁ and 927_G₂ in FIG. 9) rather than to the variable line 121. Gate lines 927 may run parallel to corresponding term wires 122 and are connected to the same row of cells 923 as that term wire 122. In other words, if the gates lines 927 are denoted by Gⱼ, then for each j, a gate line 927_Gⱼ is connected to the same group of memory cells 923 as is the term line 122 for term tⱼ. Thus, a first gate line 927_G₁ is connected to the same cells as the term wire 122 for first term t₁, a second gate line 927_G₂, is connected to the same cells as the term wire 122 for second term t₂, and so on.

In this example, the current flowing through the cell 923 depends on the state of the memristor 925, the voltage applied to the gate line 927, and the magnitude and polarity of voltage applied across cell 923. If the memristor 925 is in an inactive state, no current will flow regardless of the states of the other factors. If a low voltage (e.g., 0V) is applied to the gate line 927, no current will flow regardless of the states of the other factors. If the memristor 925 is in the active state and a positive voltage is applied to gate line 927, then current can flow through the memristor 925. The direction of the current will depend on the polarity of the voltages applied, and the magnitude of the current will depend on the magnitudes of the voltages and the resistance state of the memristor 925.

The memory crossbar array 920 with memory cells 923 can be used, in some cases, to enable gradient or gain to be calculated via a single combined backward pass, rather than by via two backward passes. This can reduce the number of clock cycles required for each iteration of gradient/gain calculation and/or reduce the number of arrays, and hence circuit size and cost. FIG. 10 illustrates an example circuit 1010 that implements this approach, as described below.

VIII. Example Interaction Computation Circuit with Combined Backward Pass

Turning to FIG. 10, an interaction computation circuit 1010 will be described. Circuit 1010 is an implementation example of the circuit 110.

Circuit 1010 includes a forward array (not illustrated) to perform a forward pass, a backward memory crossbar array 1020 (“backward array 1020” or “array 1020”) to perform a backward pass, and peripheral circuitry 1030 to drive the forward array and the backward array 1020 to perform the forward and backward passes, respectively. Both the forward array and the backward array 1020 may have the same function encoded therein in the manner described above. FIG. 10 shows the array 1020 with the CNF function CNF=(x̅₁̅∨x̅₂̅∨x̅₃̅∨x̅₄̅)∧(x̅₁̅∨x₂) encoded therein as an example, but any function (polynomial or CNF) could be encoded therein. In FIG. 10, cells 923 whose memristor has been set to an Active (conducting) state are shaded, while cells 923 whose memristor has been reset to the Inactive (non-conducting) state are white.

The forward array may be configured the same as the array 320 in FIG. 3A. The portions of the peripheral circuitry 1030 that drive the forward array may include a forward pass driver and a make/break term identification circuitry that are configured the same as the forward pass driver 331 and a make/break term identification circuitry 332 shown in FIG. 3A and described above. Because the forward array and the portions of the peripheral circuitry 1030 that drive it are configured the same as parts that have already been described above in relation to FIG. 3A, these portions of the circuit 1010 are not illustrated in FIG. 10 or described below.

The backward array 1020 includes the memory cells 923, variable lines 121 respectively corresponding to variables xᵢ (if a polynomial function) or literals lᵢ (e.g., l₁, . . . , l₈) (if a CNF function), term lines 122 respectively corresponding to terms tⱼ (e.g., t₁ and t₂), and gate lines 927 respectively corresponding to terms term tⱼ (e.g., 927_G₁ and 927_G₂), as described in relation to the array 9020 of FIG. 9. Two rows and eight columns of cells 923 are shown in FIG. 10 as an example, but any number of rows and columns may be included.

The combined backward pass may be performed based on both the make parameters s, and the break parameters zⱼ that were calculated in the forward pass. As illustrated in FIG. 10B, the peripheral circuitry 1030 includes a gate driver 1047 which determines whether to turn on or off the gate lines 927 based on the parameters s, and zⱼ during the combined backward pass. In general, if a term is either a break term or a make term, then the gate driver 1047 turns on the corresponding gate line 927, and if it is neither a make nor a break term, then the corresponding gate line 927 is turned off. Specifically, if either the parameter sⱼ or the parameter z₁ is equal to one (1) for a given term tⱼ, then the voltage V_{ON} is applied to the corresponding gate line 927_Gⱼ to turn ON the transistors 924 of the memory cells 923 connected thereto, and if both parameters sⱼ and zⱼ are equal to zero (0), then the ground voltage 0V is applied to the corresponding gate line 927_Gⱼ to turn OFF the transistors 924 of the memory cells 923 connected thereto. Put another way, the gate line driver 1047 may implement the following logic: if gᵢ ≡sⱼ+zⱼ=1, then apply VON to corresponding gate line 927_Gⱼ, and otherwise apply 0V to corresponding gate line 927_Gⱼ.

In this example, the peripheral circuitry 1030 further includes term driver 1055, which generates the input voltages Vₜⱼ to apply to the term wires 122j based on the make value parameters sⱼ of the terms tⱼ. In some examples, the circuit 1010 is configured to interchangeably handle both polynomial and CNF functions, and the term driver 1055 may be configured to generate the analog voltage Vₜⱼ such that Vₜⱼ=V₀·aⱼ·sⱼ, in a similar manner as the driver 237, wherein aⱼ are either (1) set equal to the coefficients of the terms tⱼ if the function being processed is a polynomial or (2) each set equal to 1 if the function is a CNF function. In some examples, the circuit 1010 is configured to handle polynomial functions, in which case the term driver 1055 may be configured similarly to the driver 237 and may generate the analog voltage Vₜⱼ such that Vₜⱼ=V₀·aⱼ·sⱼ, where aⱼ are equal to the coefficients of the terms tⱼ. In some examples, the circuit 1010 is configured to handle CNF functions, in which case the term driver 1055 may be configured similarly to the driver 337 and may generate the analog voltage Vₜⱼ such that Vₜⱼ=V₀·sⱼ.

In this example, the peripheral circuitry 1030 further includes variable driver 1049 to apply voltages Vₗᵢ to the variables lines 121ᵢ, respectively. The variable driver 1049 includes voltage generators 1046, each corresponding to one of the variable lines 121. Each voltage generator 1046 is configured to apply an analog voltage of Vₗᵢ=V₀xᵢ (if function is polynomial) or Vₗ, =V₀lᵢ (if function is CNF) to the variable line 121. In other words, voltage generators 1046 may act as digital to analog converters that convert the digital values of the variables xᵢ or literals 1, to analog voltages with a conversion factor of digital 1 equal to analog voltage V₀.

Thus, for each memory cell 923, the voltage Vₗᵢ=V₀xᵢ (for polynomial) or Vₗᵢ=Vol, (for CNF) will be applied to the corresponding variable wire 121 and the voltage Vₜ₁=V₀·aⱼ∜sⱼ (for polynomial) or Vₜⱼ=V₀·sⱼ(for CNF) will be applied to the corresponding term wire 122. If the memory cell 923ᵢⱼ connected to variable wire 121, and term wire 122ⱼ is in the Active (conducting) state and the corresponding gate line 927_Gⱼ is ON, then the application of the voltages Vᵢⱼ and Vₜⱼ will cause a current to flow through the memory cell 923ᵢⱼ of I₀(aⱼ·sⱼ−xᵢ), if polynomial, or I₀(sⱼ−lᵢ), if CNF. The sign (positive or negative) of the current in the forgoing expression indicates a direction of current flow, with positive indicating a current flowing from term wire 122 to variable wire 121 and negative indicating an opposite direction of flow. Then, the current Iₓᵢ or Iₗᵢ flowing through the i^{th} variable wire 121, will be the sum of the currents flowing through all of the memory cells 923 connected thereto. This current will be equal to Iₓᵢ=I₀ Σⱼ gⱼbᵢⱼ(aⱼsⱼ−xᵢ), if polynomial, or I=I₀ Σⱼ gⱼ bᵢⱼ (sⱼ−lᵢ), if CNF, in which gⱼ is the parameter mentioned above that determines whether the gate lines 927 are ON (g=1) or OFF (g=0) and bᵢⱼ is a parameter that indicates whether the memory cell 923ᵢⱼ is Active (b=1) or Inactive (b=0).

The generation of the currents I_{z} or I will be further illustrated by considering the example of the function CNF and the input values [x₁, x₂, x₃, x₄]=[1,0,1,0]. In this case, the break parameters are z₁=1 and z₂=0 and the make parameters are s₁=0 and s₂=1, as shown in FIG. 10. As a result, the voltages Vₜⱼ are applied to the term wires 122ⱼ such that Va 0 is applied to term wire 122₁ and the voltage Vₜ₂=V₀ is applied to the term wire 122₂. Concurrently, the voltages Vₗᵢ are applied to the variable wires 121ᵢ such that: Vₗ₁=V₀ is applied to variable wire 121₁, Vₗ₂=0 is applied to variable wire 121₂, Vₗ₃=0 is applied to variable wire 121₃, Vₗ₄=V₀ is applied to variable wire 121₄, V₁₅=V₀ is applied to variable wire 121₅, Vₗ₆=0 is applied to variable wire 121₆, Vₗ₇=0 is applied to variable wire 121₇, and Vₗ₈=V₀ is applied to variable wire 121₈. This results in output currents IA flowing on the variable wires 121, for literals as follows: Iₗ₁=0 flows on variable wire 121ᵢ, lₗ₂=I₀ flows on variable wire 121₂, I₁₃=I₀ flows on variable wire 121₃, Iₗ₄=−I₀ flows on variable wire 121₄, Iₗ₅=0 flows on variable wire 1215, I16=0 flows on variable wire 121₆, Iₗ₇=0 flows on variable wire 121₇, and Iₗ₈=0 flows on variable wire 121₈ (recall that a positive value for a current I or I indicates that the current I_{z} or I is flowing from term driver 1055 towards output circuitry 1035 (e.g., into voltage generators 1046), while a negative value for a current I_{z} or I indicates current flowing away from output circuitry 1035 (e.g., out of voltage generators 1046) towards term driver 1055).

The peripheral circuitry 1030 further includes backward pass output circuitry 1035 to process the currents I_{z} or I. The processing of these currents will differ depending on whether the function is a polynomial or a CNF.

In examples where the function being processed is a polynomial, the output currents I_{z} will be sensed (e.g., by a transimpedance amplifier or other current sensor) and converted to digital form, yielding a digital value equal to Σⱼ gⱼ bᵢⱼ (aⱼsⱼ−xᵢ). This value Σⱼ gⱼ bᵢⱼ (aⱼsⱼ−xᵢ) is equal to the pseudo partial derivative ΔHₓᵢ for that variable xᵢ. The gradient ΔH is the vector comprising the pseudo partial derivatives ΔHₓᵢ for each variable xᵢ. Thus, the sensed and digitally converted currents I_{z} together form the gradient.

In some examples in which circuit 1010 processes CNF functions, backward pass output circuitry 1035 includes adders 1043, each corresponding to one of the variables xₖ (which is also the literal lᵢ₌₂ₖ₋₁) and its complement x̅ₖ̅ (which is also the literal lᵢ₌₂ₖ). The adder 1043ₖ corresponding to variable xk sums the sensed analog currents I₂ₖ₋₁ and I₂ₖ or digital representations thereof. For instance, adder 1043₁ corresponds to variable xi and sums the analog currents Iₗ₁ and Iₗ₂ that are carried on variable lines 121₁ and 122₂, adder 1043₂ corresponds to variable x₂ and sums the analog currents Iₗ₃ and Iₗ₄ carried on variable lines 121₃ and 122₄, and so on.

In some examples, the adder 1043 may include a summing transimpedance amplifier, which includes an amplifier configured to receive the two analog currents Iₗ₂ₖ₋₁ and Iₗ₂ₖ and output an analog voltage signal proportional to their sum. Or, in other examples, the adder 1043 may include separate analog current sensors to sense the currents Iₗ_{₂ₖ₋₁} and Iₗ_{₂ₖ}, converting them into analog voltage signals, followed then by analog voltage summing circuitry to add the results. In still other examples, the currents Iₗ_{₂ₖ₋₁} and Iₗ_{₂ₖ} may be sensed and the results converted into digital values, in which case the adder 1043 may be a digital adder which adds together the digital representation of the currents Iₗ_{₂ₖ₋₁} and Iₗ_{₂ₖ}

In FIG. 10, the outputs of the adders 1043 are labeled as analog currents to make it easier to read the diagram, but it should be understood that in some examples the outputs of the adders 1043 may be analog voltages that represent (e.g., are proportional to) the sum of the currents or they may be digital values that represent the sum of the currents.

The backward pass output circuitry 1035 may further include analog to digital converters (ADC) 1044 which can convert values from analog to digital form at some point in the output chain. In FIG. 10, the ADCs 1044 are shown as being a last link in the output chain, such that the sensing and addition performed by the adders 1043 is fully analog. In this case, each ADC 1044ₖ corresponds to one of the variables xₖ and receives the output of the adder 1043ₖ associated with the corresponding variable xₖ. For instance, ADC 10441 corresponds to variable xi and receives the output of adder 1043₁, ADC 1044₂ corresponds to variable x₂ and receives the output of adder 1043₂, and so on. The ADC 1044ₖ converts the value to digital form, with the result being output as a gain value gainₓₖ for the corresponding variable xₖ. In other examples, the ADCs 1044 could be placed elsewhere in the chain. For instance, the sensed output currents Iₗᵢ could be converted into digital values as part of the current sensing or subsequent thereto and then these digital values may be added together by the adders 1043 through digital arithmetic, in which case the output of adders 1043 may be a digital value equal to the gain values gainₓₖ. As another example, the adders 1043 may be configured to take in analog inputs and output digital values. Regardless of where the ADC takes place, the gain values that are ultimately outputted may be given by gainₓₖ=Σⱼ gⱼb_{2k-1,j}(sⱼ−l₂ₖ₋₁)+Σⱼ gⱼb_{2k,j} (sⱼ−lₖ₂).

The operation of break-pass output circuitry 1035 may be further illustrated by considering function CNF and the input values [x₁, x₂, x₃, x₄]=[1,0,1,0], and the resulting output currents Iₗ₁=0, Iₗ₂=I₀, Iₗ₃=I₀, Iₗ₄=−I₀, Iₗ₅=0, Iₗ₆=0, Iₗ₇=0, and Iₗ₈=0, as described above. In this case, the output of the adder 1043₁ is I₀, resulting in the ADC 1044₁ outputting a gain value for variable xi of gainₓ₁=1. For all of the other adders 1044₂ to 1044₄, their outputs are zero, and consequently the gain values for variables x₂, x₃, and x₄ are each equal to zero.

### IX. Additional Examples of Interaction Computation Circuits

In the forward pass shown in FIG. 2A, make and break terms are identified by comparing the values of Σⱼ^{term} (as determined from the output currents Iₜⱼ) to Kⱼ or Kⱼ−1, where Kⱼ is the degree of the term tⱼ. This requires the peripheral circuitry 130/230 to keep track of the degree Kⱼ of each term, which adds some complexity. In some examples, this complexity can be reduced by altering the operation of the forward path. In particular, instead of applying voltages Vₓᵢ=V₀xᵢ to the variable wires 121, as described above in relation to FIG. 2B, voltages V′ₓ=V₀x̅₁̅ may be applied to the variable wires 121ᵢ, respectively. With this change, the output currents from the term wires 122ⱼ now become

$${I}_{tj}^{′} = {\sum }_{j}^{′ term} = {\sum }_{i} {b}_{ij} \overline{{x}_{ι}} ,$$

and the make/break determination circuitry can be modified to identify terms tⱼ as make terms if term

$${\sum }_{j}^{′ term} = 1 ,$$

as break terms if

$${\sum }_{j}^{′ term} = 0 ,$$

and as neither make nor break terms otherwise. Backward passes may then be performed based on these parameters in the same manner as described above in relation to any of the previously described examples.

Furthermore, in some examples, rather than merely applying binary states of Active (fully conducting) and Inactive (fully nonconducting) to the memory cells 123, the memory cells 123 may be capable of being set to multiple different active states, with each active state corresponding to a different resistance/conductance level. This may allow input scaling in the backward passes. For instance, rather than multiplying the make and break parameters s, and zⱼ by the coefficients a₁ to obtain the voltages Vₜⱼ^{break} and Vₜⱼ^{make} during the backward passes, the coefficients a₁ may be programmed into the active memory cells 123. If a given memory cell 123 is to be placed in an active state according to the encoding of the function as described above, then the actual resistance/conductance of that given memory cell 123 may be set based on the coefficient aⱼ of the term tⱼ associated with the term wire 122ⱼ that the cell 123 is coupled to. Thus, while cells 123 are still set to active and inactive states to encode the function in the manner described above, there is not just one single active state that is programmed into all of the active cells 123, but rather the active cells 123 may be set to different resistance levels to program therein the coefficient aⱼ. Then voltages V′ₜⱼ^{break}=V₀zⱼ and V′ₜⱼ^{make}=V₀sⱼ can be applied to the term wires 122j during the backward break and make passes, with the scaling against the coefficients aⱼ occurring in the memory cells 123 themselves in analog fashion rather than requiring multiplication circuits in the peripheral circuitry to scale the voltages by a₁.

In some examples, the circuit 110 can also be used to process real-valued functions with scalar variables (as opposed to the binary variables discussed elsewhere herein). In some examples, the memory cells 123 of a forward array 120 may comprise memory elements with linear input-to-output characteristics, such as memristors operating in their linear regime (e.g., with read voltage <0.2V). In some examples, memristors are chosen for the memory cells 123 of the forward array because of their rather simpler (enabled by ohm's law) resistive behavior. However, it is noted that with some peripheral tweaks, even floating-gate cells can be used as linear memory elements of memory cells 123 in the forward array 120. Memory cells of a backward array 120 may comprise memory elements with exponential input-to-output characteristics, such as floating gate memory cells operating in their subthreshold regime. Using floating-gate memory or any other device with exponential trend in their input-to-output characteristics enables performing an exponent operation locally at each memory cell 123 in the backward pass. However, in some examples, memory elements with linear trends could alternatively be used in the backward array, but this may necessitate the addition of an anti-log amplifier at the input side of the backward array 120 to perform the exponent operation.

The function of interest may be programmed into the forward and backward arrays 120 as described above. In the forward array 120, the function is programed by setting memory cells 123 into binary active and inactive states as previously described. In the backward array, the function may be programed into variable active states by programming the coefficients a₁ into the active cells 123 of a backward pass array 120 as described above. Next, real-valued input variables xᵢ may have their log computed either by external circuitry or by the peripheral circuitry 130, and then voltages representing log(x,) may be input by peripheral circuitry 130 to the variable wires 121, of the forward array 120. The variables are assumed to be within the range [xₘᵢₙ, xₘₐₓ], where xₘᵢₙ>0 and xₘₐₓ<1, and if not then they may be normalized to this range prior to the forward pass. This forward pass results in output currents Iₜⱼ on the term lines 122ⱼ proportional to the sum of the log of the variables xi included in the corresponding term tⱼ, which may be given by

$${\sum }_{j}^{log} = {\sum }_{i} log ( {x}_{i ∈ {t}_{j}} ) .$$

This value

$${\sum }_{j}^{log}$$

is equivalent to the log of the product of the variables xi included in the corresponding term tⱼ, given by

$${\prod }_{j}^{log} = log ( \prod {x}_{i ϵ {t}_{j}} ) .$$

For instance, if the function H=a₁x₁x₂x₃x₄+a₂x₁x₂x₃+a₃x₁x₂+a₄x₁x₃ is used as an example, then the following output currents Iₜⱼ would result on the term lines 122j: Iₜ₁∝ log(x₁x₂x₃x₄), Iₜ₂∝ log(x₁x₂x₃), Iₜ₃∝ log(x₁x₂), and Iₜ₄∝ log(x₁x₃). These currents Iₜⱼ may then be sensed (e.g., by a TIA) and converted to voltages Vₜⱼ.

A backward pass may then be conducted on the backward array 120. The backward pass comprises applying the voltage Vₜⱼ to the term lines 122ⱼ of the backward array 120 (which may be gate lines of floating gate transistors of memory cells 123, in some examples). Concurrently, voltages Vₛᵢ are applied to the variable lines 121ᵢ (which may be source lines of floating gate transistors of memory cells 123, in some examples) of the backward array 120, wherein each voltage Vₛᵢ is proportional to log(xi). Due to the memory element of the memory cells 123 operating in their exponential regime, the results of the application of voltages Vₜj and Vₛᵢ to gate and source lines, respectively is that currents Iₓᵢ flow along the variable lines 121ᵢ, wherein each current Iₓᵢ is equal to the product of the variable xᵢ and the pseudo-partial derivative of H with respect to xᵢ, i.e., Iₓᵢ ∝xᵢHₓᵢ. Thus, the full gradient H can be determined by dividing each of the output currents Iₓᵢ (or voltage resulting from sensing the current, or a digital representation of the same) by the corresponding variable values xᵢ.

In some examples, the input voltages Vᵢ and Vₛᵢ for the forward and backward passes, which are proportional to log(x,), may be generated based on the variable values xᵢ by a log compression stage followed by an amplification stage. The log compression stage may comprise, for each variable line 121ᵢ, an opamp with a diode connected between its output and inverting input. Voltages xᵢ′ corresponding to the values of variables xᵢ shifted by a bias v_{b1}, i.e., xᵢ′=xᵢ+v_{b1}, are applied to the inverting inputs of the opamps of the variable lines 121ᵢ via resistors R1 coupled to the inverting inputs. A reference bias voltage v_{b1} is applied to the non-inverting input of each opamp. The opamps for the lines 121ᵢ generate internal voltages Vᵢ″ (see equation 54 below, where ml is the product of thermal voltage and the subthreshold factor of the diode and R₁ is a resistance of a resistor coupled to the inverting input). This is then followed by the amplification stage, comprising amplifiers for each of the variable lines 121ᵢ which amplify the voltages Vᵢ″, respectively with gain (−AV1) to generate the voltages Vₗ(see equation 55) that are then applied to the variable lines 121, of the forward crossbar array 120. The gain AV1 may be required to amplify the log compressed into the dynamic range of the memristor input read voltage.

$${V}_{i}^{′′} = {v}_{b 1} - {m}_{1} ln \frac{{x}_{i}^{′} - {v}_{b 1}}{{R}_{1} {I}_{S}} \qquad ( 54 )$$

$${V}_{i} = {v}_{b 1} + {A}_{V 1} {m}_{1} ln \frac{{x}_{i}^{′} - {v}_{b 1}}{{R}_{1} {J}_{S}} \qquad ( 55 )$$

On the output side of the forward array 120, TIAs may be used to sense the output currents of the term lines 122ⱼ of the forward array 120. The terms lines 122 may be connected to the inverting inputs of the TIAs while bias voltages equal to Vbot (see equation (56)) may be applied to the non-inverting end of the TIAs.

$${V}_{bot} = {v}_{b 1} - {A}_{V 1} {m}_{1} ln {R}_{1} {I}_{S} \qquad ( 56 )$$

An extra term wire 122j and corresponding TIA beyond those needed for the terms t₁ may be operated during the forward pass to compute an offset current that is subtracted from the other bit line currents (see equation (57)).

$${V}_{off}^{TIA} = {v}_{bot} - {R}_{f} {G}_{off} {A}_{V 1} {m}_{1} ln {\prod }_{i = 1}^{N} ( {x}_{i}^{′} - {v}_{b 1} ) \qquad ( 57 )$$

This offset current captures the leakage currents flowing through OFF state memory cells 123. Note that such an offset correction could potentially be used in the gradient computing hardware for binary valued variables but is not necessary due to wider margins. On the other hand, in the real-valued gradient computing hardware, currents in the forward array are log compressed and vary continuously in their valid range, resulting in narrower margins. The TIAs at the output of the forward crossbar array 120 convert the term line 122j currents Iₜⱼ to proportional voltages Vⱼ^{TIA} (see equation 58, where E is the set of all edges connecting monomials with their member variables) that are subtracted from the voltage of the offset term line 122's TIA output using difference amplifiers, yielding voltages Vₑⱼ. The difference amplifier outputs Vₑⱼ constitute control gate voltages for the floating-gate elements of the memory cells 123 in the backward array 120 and are proportional to the log of monomial products (see equation (59)).

$${V}_{j}^{TIA} = {v}_{bot} - {R}_{I} {G}_{on} {A}_{V 1} {m}_{1} ln {\prod }_{i ∀ \{ {x}_{i} , {t}_{j} \} ∈ E} ( {x}_{i}^{′} - {v}_{b 1} ) - {R}_{I} {G}_{off} {A}_{V 1} {m}_{1} ln {\prod }_{i ∀ \{ {x}_{i} , {t}_{j} \} ∉ E} ( {x}_{i}^{′} - {v}_{b 1} ) \qquad ( 58 )$$

$${V}_{cj} = {V}_{off}^{TIA} - {V}_{j}^{TIA} = {R}_{f} ( {G}_{on} - {G}_{off} ) {A}_{V 1} {m}_{1} ln {\prod }_{i ∀ \{ {x}_{i} , {t}_{j} \} ∈ E} ( {x}_{i}^{′} - {v}_{b 1} ) \qquad ( 59 )$$

Concurrently with the application of the voltages V_{cj} to the term lines 122ⱼ of the backward array 120, source line voltages denoted by Vₛᵢ are applied to the variable lines 121. These voltages Vₛᵢ are proportional to log(xᵢ), and may be generated based on the internal voltages V″ₓᵢ which were used to generate the inputs to the forward array 120. For instance, the internal voltages V″ₓᵢ from the log-compression stage of the forward pass may be fed to a second amplifier stage for the backward array 120, which amplifies V″ₓᵢ to generate Vₛᵢ. The value of Vₛᵢ may be given by expression in equation (60) (generated by passing the internal voltages V″_{I} through an amplification stage with gain Aᵥ₂ and bias voltage v_{b2}).

$${V}_{si} = ( 1 + {A}_{V 2} ) {v}_{b 2} - {A}_{V 2} {v}_{b 1} + {A}_{V 2} {m}_{1} ln \frac{{x}_{i}^{′} - {v}_{b 1}}{{R}_{1} {I}_{S}} \qquad ( 60 )$$

On setting Aᵥ₂=R_{f}(Gₒᵢₙ−G_{oiff})Aᵥ₁, the net control-gate to source voltage drop across the floating-gate cells 123 and the subthreshold current through them are given by equation (61) and (62) respectively. Here V^{th}_{j,i} is the threshold voltage of the cell 123 sharing the j^{th} control-gate and i^{th} source line and m₂ is the product of subthreshold factor and thermal voltage of the device.

$${V}_{j , i}^{cgs} = {V}_{cj} - {V}_{si} = {R}_{i} ( {G}_{on} - {G}_{off} ) {A}_{V 1} {m}_{1} ln \frac{{\prod }_{i ∀ \{ {x}_{i} , {t}_{j} \} ∈ E} ( {x}_{i}^{′} - {v}_{b 1} )}{{x}_{i}^{′} - {v}_{b 1}} - ( 1 + {A}_{V 2} ) {v}_{b 2} + {A}_{V 2} {v}_{b 1} + {A}_{V 2} {m}_{1} ln {R}_{1} {I}_{S} \qquad ( 61 )$$

$${I}_{j , i} = {I}_{0} {e}^{\frac{{V}_{j , i}^{cgs} - {V}_{j , i}^{th}}{{m}_{2}}} \qquad ( 62 )$$

The threshold voltage of the cells 123 is set proportional to the coefficient (aⱼ) of the j^{th} monomial and is given by equation (63), where Vₜ₀ is the threshold of the cells 123 that correspond to monomials with coefficient equal to one. Monomials with higher coefficient values (aⱼ>1) have lower threshold voltages, resulting in higher subthreshold currents.

$${V}_{j , i}^{th} = {V}_{t 0} - {m}_{2} ln {a}_{j} \qquad ( 63 )$$

On setting R_{f}(Gₒₙ−G_{off})Aᵥ₁m₁=m₂, substituting equations (60), (62) and (63) in equation (61) and rearranging the terms, one obtains an expression for the current given by equation (64), where the constant I″₀ is given by the expression in equation (65).

$${I}_{j , i} = {I}_{0} {e}^{\frac{\begin{matrix}{m}_{2} ln \frac{{\prod }_{i ∀ \{ {x}_{i} , {t}_{j} \} ∈ E} ( {x}_{i}^{′} - {v}_{b 1} )}{{x}_{i}^{′} - {v}_{b 1}} - \\ ( 1 + {m}_{2} / {m}_{1} ) {v}_{b 2} + {m}_{2} / {m}_{1} {v}_{b 1} + {m}_{2} ln {R}_{1} {I}_{S} - {V}_{t 0} + {m}_{2} ln {a}_{j}\end{matrix}}{{m}_{2}}} = {I}_{0}^{′′} \frac{{a}_{j} {\prod }_{i ∀ \{ {x}_{i} , {t}_{j} \} ∈ E} ( {x}_{i}^{′} - {v}_{b 1} )}{{x}_{i}^{′} - {v}_{b 1}} = {I}_{0}^{′′} \frac{{a}_{j} {\prod }_{i ∀ \{ {x}_{i} , {t}_{j} \} ∈ E} {x}_{i}}{{x}_{i}} \qquad ( 64 )$$

$${I}_{0}^{′′} = {I}_{0} {e}^{\frac{- ( 1 + {m}_{2} / {m}_{1} ) {v}_{b 2} + {m}_{2} / {m}_{1} {v}_{b 1} + {m}_{2} ln {R}_{1} {I}_{S} - {V}_{t 0}}{{m}_{2}}} \qquad ( 65 )$$

$$\frac{\partial H}{\partial {x}_{i}} ∝ {I}_{i} = {\sum }_{j = 2}^{M} {I}_{j , i} = {I}_{0}^{′′} {\sum }_{j = 1}^{M} \frac{{a}_{i} {{\prod }_{i ∀ \{ {x}_{i} , {t}_{j} \} ∈ {E}^{{x}_{i}}}^{}}_{}}{{x}_{i}} \qquad ( 66 )$$

The expression of the current in equation (64) is proportional to the partial-derivative of the j^{th} monomial with respect to variable xᵢ (provided they are in the range [Xₘᵢₙ, xₘₐₓ]). The currents from all the cells in a column get summed up (according to Kirchoff s law) and this sum is proportional to the partial derivative of the high-degree polynomial function with respect to the variable corresponding to that column (see equation (66)). The output current I, on variable line 121ᵢ, which comprises the sum of the currents through the memory cells 123 connected to variable line 121ᵢ, is then sensed (e.g., converted to a voltage) by a sensor, such as a TIA.

In some examples, the forgoing real-valued gradient calculation can be incorporated into a neural network. For instance, the voltages resulting from sensing the currents Iᵢ output from each of the variable lines 121ᵢ, which represents the partial derivatives of the function with respect to the variables xᵢ, may be fed as inputs to neuron activation layers of the neural network. The output of the neuron activations may then be fed back to be used as inputs of a next iteration of forward pass on the forward array 120.

It is worth noting that while the cost/energy function of most combinatorial optimization are defined with variables x∈[0,1], a new energy function can be defined with variables x_{new} ∈[xₘᵢₙ, xₘₐₓ] by substituting x with (x_{new}−xₘᵢₙ)/(xₘₐₓ−xₘᵢₙ) in the original function. Furthermore, while the current hardware description is only valid for positive monomial coefficients (aⱼ>0), a differential mode implementation with two-bit lines per variable in the backward array 120 can enable both positive and negative monomial coefficients.

Each threshold voltage that is programmed to each floating gate cell has the following range. V^{th,min}<V^{th}_{j,i}<Vₜ₀<V^{th,max}. The threshold voltage V^{th}_{j,i}=Vₜ₀ when aⱼ=1 (see equation (63)). The absolute maximum value V^{th,max} is determined by the device properties and V^{th}_{j,i}=V^{th,max} if {xᵢ, tⱼ}∉E (or in other words, variable xᵢ is not present in monomial tⱼ). Equation (67) describes the relationship between the coefficient bit-precision (δ, in number of bits) and the threshold voltage limits when tuning error is assumed to be zero. The effective bit-precision considering non-zero threshold tuning error is lesser than this value for the same threshold voltage range.

$$δ = \frac{{V}_{t 0} - {V}^{th , min}}{{m}_{2} ln 2} \qquad ( 67 )$$

To maintain subthreshold operation regime, the control-gate to source voltage applied across each floating-gate cell is limited by 0<V^{cgs}_{j,1}<V^{th,min}. According to equation (61), the maximum limit is achieved for the case shown in equation (68) (when the corresponding monomial comprises of two variables, with both equal to the maximum value, xₘₐₓ).

$$( 68 )$$

$${V}_{j , l}^{cgs} = {m}_{2} ln {x}_{max} - ( 1 + {m}_{2} / {m}_{1} ) {v}_{b 2} + {m}_{2} / {m}_{1} {v}_{b 1} + {m}_{2} ln {R}_{1} {I}_{S} = {V}^{th , min}$$

On rearranging the terms in equation (68), it gives an expression for a minimum value for the bias voltage v_{b2}, as described in equation (69). The bias voltage is ultimately set to this value to allow maximum

$${v}_{b 2} \geq \frac{{m}_{2} ln {x}_{max} + {m}_{2} / {m}_{1} {v}_{b 1} + {m}_{2} ln {R}_{1} {I}_{S} - {V}^{th , min}}{1 + {m}_{2} / {m}_{1}} \qquad ( 69 )$$

The minimum limit for V^{cgs}_{j,1} is reached when all the variables in the monomial with the highest degree (K) are set to the minimum value, xₘᵢₙ (see equation (70)). Substituting for the minimum value for the bias voltage v_{b2} and rearranging the terms, one gets the expression in equation (71).

$$( 70 )$$

$${V}_{j , l}^{cgs} = {m}_{2} ( K - 1 ) ln {x}_{min} - ( 1 + {m}_{2} / {m}_{1} ) {v}_{b 2} + {m}_{2} / {m}_{1} {v}_{b 1} + {m}_{2} ln {R}_{1} {I}_{S} = 0$$

$$K \leq 1 + \frac{ln {x}_{max} - {V}^{th , min} / {m}_{2}}{ln {x}_{min}} \qquad ( 71 )$$

For a given range for the variables (xₘᵢₙ, xₘₐₓ), this highlights a trade-off in the maximum order of the monomial with the bit-precision of the monomial coefficients. Note that for xₘₐₓ≤1, the denominator in equation (71) is negative and therefore for larger values of the maximum degree K of the polynomial, higher values of V^{th,max} is required. Higher values for V^{th,max} mean lesser bit-precision for monomial coefficients. Furthermore, for a fixed value of V^{th,min} there exists a trade off between the maximum order and the dynamic range of the variables (ζ=xₘₐₓ/xₘᵢₙ). Larger values of K are possible with smaller values of ζ, which also results in smaller swing in the forward crossbar array 120 input voltages, Vₓᵢ. Therefore, for smaller values of (, higher values of the gain Avi is required. This results in higher power consumption and susceptibility to PVT variations.

In the description above, various types of electronic circuitry are described. As used herein, “electronic” is intended to be understood broadly to include all types of circuitry utilizing electricity, including digital and analog circuitry, direct current (DC) and alternating current (AC) circuitry, and circuitry for converting electricity into another form of energy and circuitry for using electricity to perform other functions. In other words, as used herein there is no distinction between “electronic” circuitry and “electrical” circuitry.

It is to be understood that both the general description and the detailed description provide examples that are explanatory in nature and are intended to provide an understanding of the present disclosure without limiting the scope of the present disclosure. Various mechanical, compositional, structural, electronic, and operational changes may be made without departing from the scope of this description and the claims. In some instances, well-known circuits, structures, and techniques have not been shown or described in detail in order not to obscure the examples. Like numbers in two or more figures represent the same or similar elements.

In addition, the singular forms “a”, “an”, and “the” are intended to include the plural forms as well, unless the context indicates otherwise. Moreover, the terms “comprises”, “comprising”, “includes”, and the like specify the presence of stated features, steps, operations, elements, and/or components but do not preclude the presence or addition of one or more other features, steps, operations, elements, components, and/or groups. Components described as connected may be electronically or mechanically directly connected, or they may be indirectly connected via one or more intermediate components, unless specifically noted otherwise. Mathematical and geometric terms are not necessarily intended to be used in accordance with their strict definitions unless the context of the description indicates otherwise, because a person having ordinary skill in the art would understand that, for example, a substantially similar element that functions in a substantially similar way could easily fall within the scope of a descriptive term even though the term also has a strict definition.

And/or: Occasionally the phrase “and/or” is used herein in conjunction with a list of items. This phrase means that any combination of items in the list—from a single item to all of the items and any permutation in between—may be included. Thus, for example, “A, B, and/or C” means “one of {A}, {B}, {C}, {A, B}, {A, C}, {C, B}, and {A, C, B}”.

Elements and their associated aspects that are described in detail with reference to one example may, whenever practical, be included in other examples in which they are not specifically shown or described. For example, if an element is described in detail with reference to one example and is not described with reference to a second example, the element may nevertheless be claimed as included in the second example.

Unless otherwise noted herein or implied by the context, when terms of approximation such as “substantially,” “approximately,” “about,” “around,” “roughly,” and the like, are used, this should be understood as meaning that mathematical exactitude is not required and that instead a range of variation is being referred to that includes but is not strictly limited to the stated value, property, or relationship. In particular, in addition to any ranges explicitly stated herein (if any), the range of variation implied by the usage of such a term of approximation includes at least any inconsequential variations and also those variations that are typical in the relevant art for the type of item in question due to manufacturing or other tolerances. In any case, the range of variation may include at least values that are within ±1% of the stated value, property, or relationship unless indicated otherwise.

Further modifications and alternative examples will be apparent to those of ordinary skill in the art in view of the disclosure herein. For example, the devices and methods may include additional components or steps that were omitted from the diagrams and description for clarity of operation. Accordingly, this description is to be construed as illustrative only and is for the purpose of teaching those skilled in the art the general manner of carrying out the present teachings. It is to be understood that the various examples shown and described herein are to be taken as exemplary. Elements and materials, and arrangements of those elements and materials, may be substituted for those illustrated and described herein, parts and processes may be reversed, and certain features of the present teachings may be utilized independently, all as would be apparent to one skilled in the art after having the benefit of the description herein. Changes may be made in the elements described herein without departing from the scope of the present teachings and following claims.

It is to be understood that the particular examples set forth herein are non-limiting, and modifications to structure, dimensions, materials, and methodologies may be made without departing from the scope of the present teachings.

Other examples in accordance with the present disclosure will be apparent to those skilled in the art from consideration of the specification and practice of the invention disclosed herein. It is intended that the specification and examples be considered as exemplary only, with the following claims being entitled to their fullest breadth, including equivalents, under the applicable law.

What is claimed is:

1. An information processing system comprising:
an interaction computation circuit configured to compute interactions between variables of an arbitrary-order function, comprising:
one or more memory crossbar arrays (“arrays”), each configured to encode the function such that:
first wires of the respective array correspond respectively to variables or literals of the function;
second wires of the respective array, transverse to the first wires, correspond respectively to terms of the function; and
memory cells of the respective array are set to an active state if the variable or the literal corresponding to one of the first wires coupled to the respective memory cell is included in the term corresponding to one of the second wires coupled to the respective memory cell; and
peripheral circuitry to process inputs to and outputs from the arrays;
wherein the interaction computation circuit is configured to compute the interactions in parallel at least in part by in-memory computation in the arrays, including conducting a forward pass and one or more backward passes on the arrays, with inputs for the backward passes determined by the peripheral circuitry based on outputs of the forward pass.

2. The system of claim 1,
wherein the function is an objective function of an optimization problem.

3. The system of claim 2,
wherein the optimization problem is a combinatorial optimization problem.

4. The system of claim 1,
wherein:
the function is a polynomial with a degree K, with K≥3, and the terms comprise monomials of the polynomial, or
the function is a Boolean equation in conjunctive normal form (CNF) of complexity K (“CNF function”), with K≥3, and the terms comprise clauses of the CNF function.

5. The system of claim 1,
wherein the interactions between the variables comprise a gradient, a gain, break values, and/or make values.

6. The system of claim 1,
wherein the arrays comprise a single memory crossbar array on which both the forward pass and the one or more backward passes are conducted.

7. The system of claim 1,
wherein the arrays comprise a first memory crossbar array (“first array”) and a second memory crossbar array (“second array”), the forward pass is conducted on the first array and at least one of the one or more backward passes is conducted on the second array.

8. The system of claim 7,
wherein the one or more backward passes comprises a single backward pass conducted on the second array.

9. The system of claim 8,
wherein the function is a Boolean equation in conjunctive normal form (CNF) of complexity K (“CNF function”), with K≥3, the terms comprise clauses of the CNF function, and the interactions comprise break values;
wherein the single backward pass generates the break values; and
wherein the information processing system is configured to solve a CNF satisfaction problem according to a WalkSAT/SKC algorithm by iteratively computing the interactions by the interaction computation circuit, with the break values generated from output of the second array in one iteration used to determine inputs to the first array for a next iteration.

10. The system of claim 8,
wherein the memory cells of the second array comprise three-terminal memory cells and the interactions comprise gradients.

11. The system of claim 10,
wherein one of:
the function is a polynomial with a degree K, with K≥3, and the terms comprise monomials of the polynomial, and
the function is a Boolean equation in conjunctive normal form (CNF) of complexity K (“CNF function”), with K≥3, and the terms comprise clauses of the CNF function.

12. The system of claim 7,
wherein the arrays comprise a third memory crossbar array (“third array”); and
wherein the one or more backward passes include a backward-make pass conducted on the second array to determine make values and a backward-break pass conducted on the third array to determine break values; and
wherein the interactions comprise a gradient and the peripheral circuitry is configured to determine the gradient by subtracting the break values from the make values.

13. The system of claim 12,
wherein the peripheral circuitry is configured to:
conduct the forward pass by applying signals corresponding to an input variable vector and/or a complement thereof to the first wires of the first array and observing forward-pass outputs from the second wires of the first array;
identify make terms and break terms based on the forward-pass outputs;
conduct the backward-make pass by applying signals to the second wires of the second array based on the identification of the make terms and observing make-pass outputs from the first wires of the second array;
generate the make values for each of the variables based on the make-pass outputs;
conduct the backward-break pass by applying signals to the second wires of the third array based on the identification of the break terms and observing break-pass outputs from the first wires of the third array;
generate the break values for each of the variables based on the break-pass outputs.

14. The system of claim 12,
wherein one of:
the function is a polynomial with a degree K, with K≥3, and the terms comprise monomials of the polynomial, and
the function is a Boolean equation in conjunctive normal form (CNF) of complexity K (“CNF function”), with K≥3, and the terms comprise clauses of the CNF function.

15. The system of claim 7,
wherein the interaction computation circuit is configured to execute multiple threads concurrently and to conduct the forward pass for one thread on the first array while concurrently conducting the one or more backward passes of another thread on one or more other arrays including the second array.

16. The system of claim 1,
wherein the memory cells comprise memristor cells or flash memory cells.

17. A method of computing interactions between variables of an arbitrary-order function, comprising:
encoding the function in one or more memory crossbar arrays (“arrays”) such that:
first wires of the respective array correspond respectively to variables or literals of the function;
second wires of the respective array, transverse to the first wires, correspond respectively to terms of the function; and
memory cells of the respective array are set to an active state if the variable or the literal corresponding to one of the first wires coupled to the respective memory cell is included in the term corresponding to one of the second wires coupled to the respective memory cell; and
computing the interactions in parallel at least in part by in-memory computation in the arrays, including conducting a forward pass and one or more backward passes on the arrays, with inputs for the backward passes determined based on outputs of the forward pass.

18. The method of claim 17,
wherein the function is an objective function of an optimization problem.

19. The method of claim 18,
wherein the optimization problem is a combinatorial optimization problem.

20. The method of claim 17,
wherein the interactions between the variables comprise a gradient, break values, and/or make values.

21. The method of claim 17,
wherein the arrays comprise a first memory crossbar array (“first array”) and a second memory crossbar array (“second array”), the forward pass is conducted on the first array and at least one of the one or more backward passes is conducted on the second array.

22. A hardware accelerator module, comprising:
one or more memory crossbar arrays (“arrays”), each configured to encode an arbitrary-order function such that:
first wires of the respective array correspond respectively to variables or literals of the function;
second wires of the respective array, transverse to the first wires, correspond respectively to terms of the function; and
memory cells of the respective array are set to an active state if the variable or the literal corresponding to one of the first wires coupled to the respective memory cell is included in the term corresponding to one of the second wires coupled to the respective memory cell; and
peripheral circuitry configured to compute the gradient by:
conducting a forward pass by applying signals corresponding to an input variable vector or a complement thereof to the first wires of a first array of the arrays and observing forward pass outputs from the second wires of the first array;
conducting a backward pass by applying signals to the second wires of a second array of the arrays based on the forward pass outputs and observing backward pass outputs from the first wires of the second array; and
computing the gradient based on the backward pass outputs.

23. The gradient computation hardware accelerator of claim 22,
wherein the peripheral circuitry is configured to:
identify make and break terms based on the forward pass outputs;
generate make values for each of the variables based on the backward pass outputs;
conduct a second backward pass by applying signals to the second wires of a third array of the arrays based on the identification of the break terms and observing second backward pass outputs from the first wires of the third array;
generate break values for each of the variables based on the second backward pass outputs; and
compute the gradient by subtracting the break values from the make values.

24. The gradient computation hardware accelerator of claim 23,
wherein the first, second, and third arrays are separate arrays.
